(19) United States
(12) Patent Application Publication
(10) Pub. No.: US 2026/0043878 A1
(43) Pub. Date: Feb. 12, 2026

(54) MAGNETIC SENSOR

(71) Applicant: TDK CORPORATION, Tokyo (JP)

(72) Inventors: Hidekazu KOJIMA, Tokyo (JP); Hirokazu Takahashi, Tokyo (JP); Takashi Saito, Tokyo (JP); Satoshi Miura, Tokyo (JP)

(73) Assignee: TDK CORPORATION, Tokyo (JP)

(21) Appl. No.: 19/272,184

(22) Filed: Jul. 17, 2025

(30) Foreign Application Priority Data
Aug. 9, 2024 (JP) 2024-134644

(51) Int. Cl. G01R 33/09

(52) U.S. Cl. CPC G01R 33/09

(57) ABSTRACT

A magnetic sensor includes: a substrate having a top surface; an insulating layer having a top surface including a first inclined surface and a second inclined surface that are inclined relative to the top surface of the substrate and oriented in directions different from each other; a first MR element disposed above the first inclined surface; a second MR element disposed above the second inclined surface; and two magnetic field generators that are disposed from the first inclined surface to the second inclined surface, with the first MR element and the second MR element interposed therebetween, the two magnetic field generators each being configured to apply a bias magnetic field to the first MR element and the second MR element.

### CROSS REFERENCE TO RELATED APPLICATIONS

This application claims the benefit of Japanese Priority Patent Application No. 2024-134644 filed on Aug. 9, 2024, the entire contents of which are incorporated herein by reference.

### BACKGROUND

The disclosure relates to a magnetic sensor configured to be capable of applying a bias magnetic field to a magnetoresistive element.

In recent years, magnetic sensors have been used for a variety of applications. Examples of known magnetic sensors include one that uses a spin-valve magnetoresistive element provided on a substrate. The spin-valve magnetoresistive element includes a magnetization pinned layer whose magnetization direction is fixed, a free layer whose magnetization direction is variable depending on the direction of an applied magnetic field, and a gap layer disposed between the magnetization pinned layer and the free layer. In many cases, spin-valve magnetoresistive elements provided on a substrate are configured to have sensitivity to a magnetic field in a direction parallel to the surface of the substrate. Such magnetoresistive elements are thus suitable for detecting magnetic fields that changes in direction within a plane parallel to the surface of the substrate.

On the other hand, a system including a magnetic sensor may be intended to detect a magnetic field containing a component in a direction perpendicular to the surface of a substrate by using magnetoresistive elements provided on the substrate. In such a case, the magnetic field containing the component in the direction perpendicular to the surface of the substrate can be detected by disposing the magnetoresistive elements on an inclined surface formed on the substrate.

Incidentally, some magnetic sensors include a means for applying a bias magnetic field to the magnetoresistive element. The bias magnetic field is used, for example, to cause the magnetoresistive element to respond linearly to a change in the strength of the target magnetic field, which is the magnetic field to be detected. In a magnetic sensor that uses a spin-valve magnetoresistive element, the bias magnetic field is used also to make the free layer have a single magnetic domain and to orient the magnetization direction of the free layer in a certain direction, when there is no target magnetic field.

JP 2006-308573 A discloses a triaxial magnetic sensor which is a triaxial magnetic sensor including an X-axis sensor, a Y-axis sensor, and a Z-axis sensor in one substrate, and configured such that a magnetoresistive element of the Z-axis sensor is provided on an inclined surface of a protrusion formed so as to protrude from a plane of the substrate. The magnetoresistive element is formed by a plurality of magnetoresistive element bars being connected in series by bias magnets.

JP 2016-176911 A discloses a magnetic sensor including a magnetoresistive element and two magnetic field generators disposed with the magnetoresistive element interposed therebetween. Each of the magnetic field generators includes an antiferromagnetic layer and a ferromagnetic layer stacked together, and is configured to apply a bias magnetic field to the magnetoresistive element.

However, when an attempt is made to form a magnetic field generator on an inclined surface as in the magnetic sensor as disclosed in JP 2006-308573 A, a position and an inclination angle of an end portion of the magnetic field generator located above the inclined surface are likely to vary, compared with the case where the magnetic field generator is formed on a plane. As a result, there has been a problem that a strength of a bias magnetic field to be applied to a magnetoresistive element varies, which results in variation in the characteristics of the magnetic sensor.

### SUMMARY

A magnetic sensor according to one embodiment of the disclosure includes: a substrate having a reference plane; a support member having a top surface including a first inclined surface and a second inclined surface that are inclined relative to the reference plane and oriented in directions different from each other; a first magnetoresistive element disposed above the first inclined surface; a second magnetoresistive element disposed above the second inclined surface; and a first magnetic field generator and a second magnetic field generator that are disposed from the first inclined surface to the second inclined surface, with the first magnetoresistive element and the second magnetoresistive element interposed between the first magnetic field generator and the second magnetic field generator, the first magnetic field generator and the second magnetic field generator each being configured to apply a bias magnetic field to the first magnetoresistive element and the second magnetoresistive element.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device including a magnetic sensor according to a first example embodiment of the disclosure.

FIG. 2 is a side view showing the magnetic sensor device shown in FIG. 1.

FIG. 3 is a functional block diagram showing a configuration of the magnetic sensor device shown in FIG. 1.

FIG. 4 is a circuit diagram showing a circuit configuration of a first detection circuit in the first example embodiment of the disclosure.

FIG. 5 is a circuit diagram showing a circuit configuration of a second detection circuit in the first example embodiment of the disclosure.

FIG. 6 is a plan view showing a part of the magnetic sensor according to the first example embodiment of the disclosure.

FIG. 7 is a cross-sectional view showing a part of a cross section at a position indicated by the 7-7 line in FIG. 6.

FIG. 8 is a cross-sectional view showing a part of a cross section at a position indicated by the 8-8 line in FIG. 6.

FIG. 9 is a plan view showing magnetoresistive elements, magnetic field generators, lower electrodes, and upper electrodes of the first example embodiment of the disclosure.

FIG. 10 is a perspective view showing the magnetoresistive element of the first example embodiment of the disclosure.

FIG. 11 is a side view showing the magnetic field generator of the first example embodiment of the disclosure.

FIG. 12 is a cross-sectional view showing a part of the magnetic sensor of the first example embodiment of the disclosure.

FIG. 13 is a cross-sectional view showing a part of the magnetic sensor of the first example embodiment of the disclosure.

FIG. 14 is an explanatory diagram for describing a shape of a side surface of the magnetic field generator in the first example embodiment of the disclosure.

FIG. 15 is a cross-sectional view showing one process in a manufacturing method of the magnetic sensor according to the first example embodiment of the disclosure.

FIG. 16 is a cross-sectional view showing a process following the process shown in FIG. 15.

FIG. 17 is a plan view showing magnetoresistive elements, magnetic field generators, lower electrodes, and upper electrodes of a first modification example of the magnetic sensor according to the first example embodiment of the disclosure.

FIG. 18 is a side view showing a magnetic field generator of a second modification example of the magnetic sensor according to the first example embodiment of the disclosure.

FIG. 19 is a side view showing a magnetic field generator of a third modification example of the magnetic sensor according to the first example embodiment of the disclosure.

FIG. 20 is a side view showing a magnetic field generator of a fourth modification example of the magnetic sensor according to the first example embodiment of the disclosure.

FIG. 21 is a side view showing a magnetic field generator of a fifth modification example of the magnetic sensor according to the first example embodiment of the disclosure.

FIG. 22 is a side view showing a magnetic field generator of a sixth modification example of the magnetic sensor according to the first example embodiment of the disclosure.

FIG. 23 is a cross-sectional view showing a part of a magnetic sensor of a seventh modification example of the magnetic sensor according to the first example embodiment of the disclosure.

FIG. 24 is a plan view showing a part of a magnetic sensor according to a second example embodiment of the disclosure.

FIG. 25 is a cross-sectional view showing a part of a cross section at a position indicated by the 25-25 line in FIG. 24.

FIG. 26 is a plan view showing a part of a magnetic sensor according to a third example embodiment of the disclosure.

FIG. 27 is a plan view showing a part of a magnetic sensor according to a fourth example embodiment of the disclosure.

### DETAILED DESCRIPTION

An object of the disclosure is to provide a magnetic sensor capable of suppressing a variation in a strength of a bias magnetic field to be applied to a magnetoresistive element.

In the following, some example embodiments and modification examples of the disclosure are described in detail with reference to the accompanying drawings. Note that the following description is directed to illustrative examples of the disclosure and not to be construed as limiting the technology. Elements including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Similar elements are denoted with the same reference numerals to avoid redundant descriptions.

### First Example Embodiment

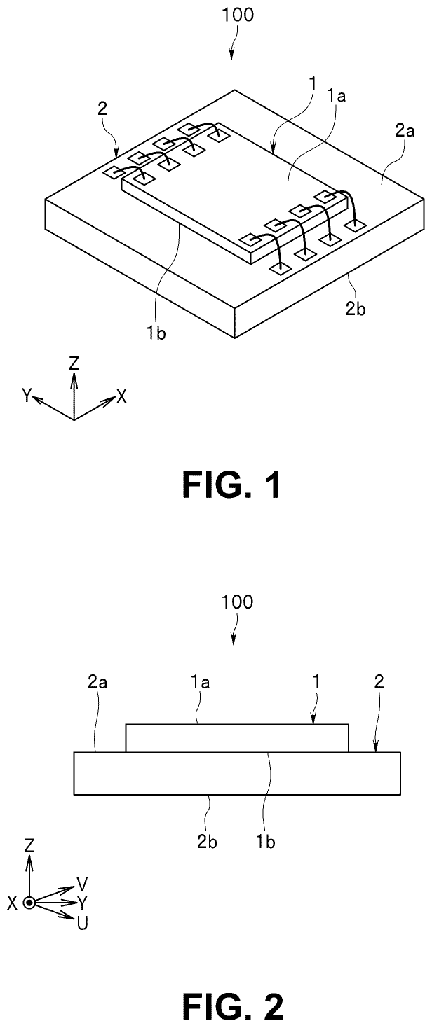

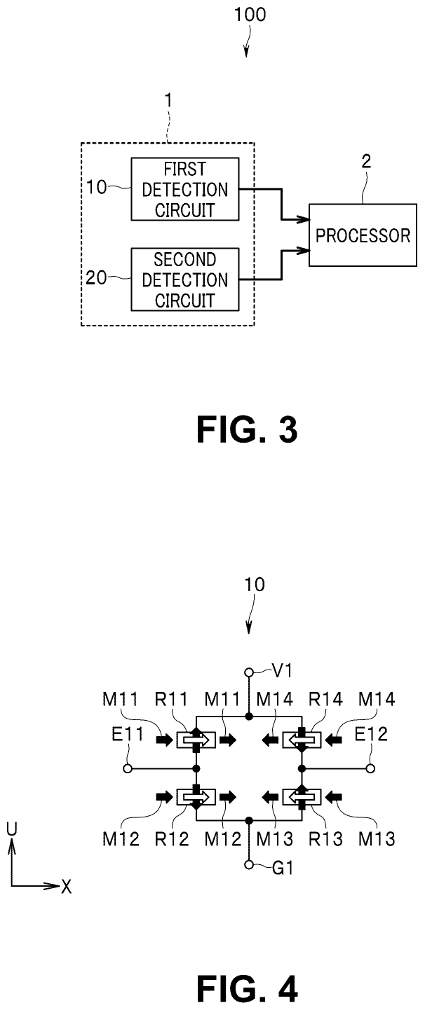

A configuration of a magnetic sensor device including a magnetic sensor according to a first example embodiment of the disclosure will initially be described with reference to FIGS. 1 through 3. FIG. 1 is a perspective view showing a magnetic sensor device 100. FIG. 2 is a side view showing the magnetic sensor device 100. FIG. 3 is a functional block diagram showing the configuration of the magnetic sensor device 100.

The magnetic sensor device 100 of the example embodiment includes a magnetic sensor 1 according to the example embodiment and a processor 2. The magnetic sensor 1 is configured to detect a target magnetic field, which is a magnetic field to be detected by the magnetic sensor 1, and to generate at least one detection signal. The magnetic sensor 1 may be a geomagnetic field sensor that detects the geomagnetic field, a magnetic sensor for a position detection device that detects a position of a magnet moving in a specific direction, a magnetic sensor for angle sensors or magnetic encoders that detects a rotating magnetic field, or a magnetic sensor for current sensors that detects a magnetic field generated by a current to be detected.

The processor 2 is configured to generate at least one detection value having a correspondence with the target magnetic field, based on the at least one detection signal. The processor 2 is constituted, for example, of an application-specific integrated circuit (ASIC).

The magnetic sensor 1 and the processor 2 are each in a form of a chip having a rectangular parallelepiped shape. The magnetic sensor 1 includes a top surface 1a and a bottom surface 1b located on opposite sides of each other, and four side surfaces connecting the top surface 1a and the bottom surface 1b. The processor 2 includes a top surface 2a and a bottom surface 2b located on opposite sides of each other, and four side surfaces connecting the top surface 2a and the bottom surface 2b. The magnetic sensor 1 is mounted on the top surface 2a of the processor 2 in such an orientation that the bottom surface 1b of the magnetic sensor 1 faces the top surface 2a of the processor 2. The magnetic sensor 1 is bonded to the processor 2 by an adhesive, for example.

Now, X, Y, and Z directions are defined as shown in FIGS. 1 and 2. The X direction, the Y direction, and the Z direction are orthogonal to one another. In the example embodiment, the Z direction is a direction perpendicular to the top surface 1a of the magnetic sensor 1 and from the bottom surface 1b to the top surface 1a of the magnetic sensor 1. The opposite directions to the X, Y, and Z directions will be expressed as −X, −Y, and −Z directions, respectively.

Hereinafter, the term “above” refers to positions located forward of a reference position in the Z direction, and “below” refers to positions opposite to “above” with respect to the reference position. For each component of the magnetic sensor 1, the term “top surface” refers to a surface of the component lying at the end thereof in the Z direction, and “bottom surface” refers to a surface of the component lying at the end thereof in the −Z direction. The expression “when viewed in a specific direction (e.g., the Z direction)” means that an object is viewed from a position away in the specific direction or in one direction parallel to the specific direction.

In addition, as shown in FIG. 2, U and V directions are defined as follows. The U direction is a direction rotated from the Y direction to the −Z direction. The V direction is a direction rotated from the Y direction to the Z direction. In the example embodiment, in particular, the U direction is set to a direction rotated from the Y direction to the −Z direction by α, and the V direction is set to a direction rotated from the Y direction to the Z direction by α. Note that α is an angle greater than 0° and smaller than 90°. A −U direction refers to a direction opposite to the U direction, and a −V direction refers to a direction opposite to the V direction. The U direction and the V direction both are orthogonal to the X direction.

The magnetic sensor 1 includes a plurality of first pads (electrode pads) provided on the top surface 1a. The processor 2 includes a plurality of second pads (electrode pads) provided on the top surface 2a. In the magnetic sensor 1, of the plurality of first pads and the plurality of second pads, two corresponding pads are connected to each other by a bonding wire.

The magnetic sensor 1 includes a first detection circuit 10 and a second detection circuit 20. The first and second detection circuits 10 and 20 and the processor 2 are connected via the plurality of first pads, the plurality of second pads, and a plurality of bonding wires.

The first and second detection circuits 10 and 20 each include a plurality of magnetic detection elements, and are configured to detect the target magnetic field and generate at least one detection signal. In the example embodiment, in particular, the plurality of magnetic detection elements are a plurality of magnetoresistive elements. The magnetoresistive elements will hereinafter be referred to as MR elements.

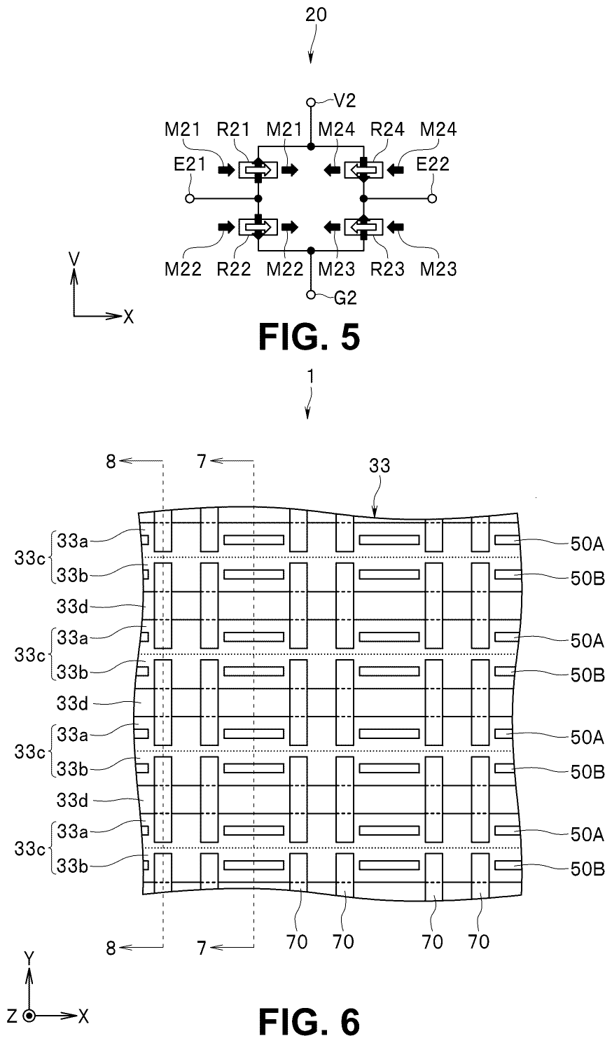

Next, circuit configurations of the first and second detection circuits 10 and 20 will be described with reference to FIGS. 4 and 5. FIG. 4 is a circuit diagram showing the circuit configuration of the first detection circuit 10. FIG. 5 is a circuit diagram showing the circuit configuration of the second detection circuit 20.

The first detection circuit 10 is configured to detect a component of the target magnetic field in a direction parallel to the U direction, and generate at least one first detection signal having a correspondence with the component. The second detection circuit 20 is configured to detect a component of the target magnetic field in a direction parallel to the V direction, and generate at least one second detection signal having a correspondence with the component.

As shown in FIG. 4, the first detection circuit 10 includes four resistor sections R11, R12, R13, and R14, a power supply port V1, a ground port G1, a first output port E11, and a second output port E12. A plurality of MR elements of the first detection circuit 10 constitute the resistor sections R11, R12, R13, and R14.

The resistor section R11 is provided between the power supply port V1 and the first output port E11. The resistor section R12 is provided between the first output port E11 and the ground port G1. The resistor section R13 is provided between the second output port E12 and the ground port G1. The resistor section R14 is provided between the power supply port V1 and the second output port E12.

As shown in FIG. 5, the second detection circuit 20 includes four resistor sections R21, R22, R23, and R24, a power supply port V2, a ground port G2, a first output port E21, and a second output port E22. A plurality of MR elements of the second detection circuit 20 constitute the resistor sections R21, R22, R23, and R24.

The resistor section R21 is provided between the power supply port V2 and the first output port E21. The resistor section R22 is provided between the first output port E21 and the ground port G2. The resistor section R23 is provided between the second output port E22 and the ground port G2. The resistor section R24 is provided between the power supply port V2 and the second output port E22.

A voltage or current of a specific magnitude is applied to each of the power supply ports V1 and V2. Each of the ground ports G1 and G2 is connected to the ground.

Hereinafter, the plurality of MR elements of the first detection circuit 10 will be referred to as a plurality of first MR elements 50A. The plurality of MR elements of the second detection circuit 20 will be referred to as a plurality of second MR elements 50B. Since the first and second detection circuits 10 and 20 are components of the magnetic sensor 1, it can be said that the magnetic sensor 1 includes the plurality of first MR elements 50A and the plurality of second MR elements 50B. Any given MR element will be denoted by the reference numeral 50.

In the example embodiment, in particular, the MR element 50 is a spin-valve MR element. The MR element 50 includes a magnetization pinned layer whose magnetization direction is fixed, a free layer whose magnetization direction is variable depending on the direction of the target magnetic field, and a gap layer disposed between the magnetization pinned layer and the free layer. The MR element 50 may be a tunneling magnetoresistive (TMR) element or a giant magnetoresistive (GMR) element. In the TMR element, the gap layer is a tunnel barrier layer. In the GMR element, the gap layer is a nonmagnetic conductive layer. The resistance of the MR element 50 changes with the angle that the magnetization direction of the free layer forms with respect to the magnetization direction of the magnetization pinned layer. The resistance of the MR element 50 is at its minimum value when the foregoing angle is 0°, and at its maximum value when the foregoing angle is 180°. In each MR element 50, the free layer has a shape anisotropy in which the direction of the magnetization easy axis is orthogonal to the magnetization direction of the magnetization pinned layer.

In FIGS. 4 and 5, the plurality of solid arrows overlapping the respective resistor sections indicate the magnetization directions of the magnetization pinned layers of the MR elements 50. The plurality of hollow arrows overlapping the respective resistor sections indicate the magnetization directions of the free layers of the MR elements 50 when no target magnetic field is applied to the MR elements 50.

In the example shown in FIG. 4, the magnetization directions of the magnetization pinned layers in each of the resistor sections R11 and R13 are in the U direction. The magnetization directions of the magnetization pinned layers in each of the resistor sections R12 and R14 are in the −U direction. The free layer in each of the plurality of first MR elements 50A has a shape anisotropy in which the direction of the magnetization easy axis is parallel to the X direction. The magnetization directions of the free layers in each of the resistor sections R11 and R12 are in the X direction when no target magnetic field is applied to the first MR elements 50A. The magnetization directions of the free layers in each of the resistor sections R13 and R14 in the foregoing case are in the −X direction.

In the example shown in FIG. 5, the magnetization directions of the magnetization pinned layers in each of the resistor sections R21 and R23 are in the V direction. The magnetization directions of the magnetization pinned layers in each of the resistor sections R22 and R24 are in the −V direction. The free layer in each of the plurality of second MR elements 50B has a shape anisotropy in which the direction of the magnetization easy axis is parallel to the X direction. The magnetization directions of the free layers in each of the resistor sections R21 and R22 are in the X direction when no target magnetic field is applied to the second MR elements 50B. The magnetization directions of the free layers in each of the resistor sections R23 and R24 in the foregoing case are in the −X direction.

The magnetic sensor 1 further includes at least one magnetic field generator that generates a bias magnetic field to be applied to the at least one MR element 50. In the example embodiment, in particular, the magnetic sensor 1 includes a plurality of magnetic field generators 70, as at least one magnetic field generator.

In FIG. 4, the arrows denoted by the reference numerals M11, M12, M13, and M14 indicate the directions of the bias magnetic fields applied to the plurality of first MR elements 50A by the plurality of magnetic field generators 70. In the resistor sections R11 and R12, a bias magnetic field in the X direction is applied to the plurality of first MR elements 50A by the plurality of magnetic field generators 70. In the resistor sections R13 and R14, a bias magnetic field in the −X direction is applied to the plurality of first MR elements 50A by the plurality of magnetic field generators 70.

In FIG. 5, the arrows denoted by the reference numerals M21, M22, M23, and M24 indicate the directions of the bias magnetic fields applied to the plurality of second MR elements 50B by the plurality of magnetic field generators 70. In the resistor sections R21 and R22, a bias magnetic field in the X direction is applied to the plurality of second MR elements 50B by the plurality of magnetic field generators 70. In the resistor sections R23 and R24, a bias magnetic field in the −X direction is applied to the plurality of second MR elements 50B by the plurality of magnetic field generators 70.

Note that the magnetization directions of the magnetization pinned layers, the directions of the magnetization easy axes of the free layers, and the directions of the bias magnetic fields applied to the MR elements 50 by the plurality of magnetic field generators 70 may be slightly deviated from the foregoing directions, in light of the production accuracy of the MR elements 50 and the magnetic field generators 70. The magnetization pinned layers may be configured to be magnetized to include magnetization components in the foregoing directions as their main components. In such a case, the magnetization directions of the magnetization pinned layers are the same or substantially the same as the foregoing directions.

Next, the first and second detection signals will be described. The first detection signal will initially be described with reference to FIG. 4. As the strength of the component of the target magnetic field in the direction parallel to the U direction changes, the resistance of each of the resistor sections R11 to R14 of the first detection circuit 10 changes either so that the resistances of the resistor sections R11 and R13 increase and the resistances of the resistor sections R12 and R14 decrease, or so that the resistances of the resistor sections R11 and R13 decrease and the resistances of the resistor sections R12 and R14 increase. Thereby the electric potential at each of the first and second output ports E11 and E12 changes. The first detection circuit 10 is configured to generate a signal corresponding to the electric potential at the first output port E11 as a first detection signal S11, and generate a signal corresponding to the electric potential at the second output port E12 as a first detection signal S12.

Next, a second detection signal will be described with reference to FIG. 5. As the strength of the component of the target magnetic field in the direction parallel to the V direction changes, the resistance of each of the resistor sections R21 to R24 of the second detection circuit 20 changes either so that the resistances of the resistor sections R21 and R23 increase and the resistances of the resistor sections R22 and R24 decrease, or so that the resistances of the resistor sections R21 and R23 decrease and the resistances of the resistor sections R22 and R24 increase. Thereby the electric potential at each of the first and second output ports E21 and E22 changes. The second detection circuit 20 is configured to generate a signal corresponding to the electric potential at the first output port E21 as a second detection signal S21, and generate a signal corresponding to the electric potential at the second output port E22 as a second detection signal S22.

Next, the operation of the processor 2 will be described. The processor 2 is configured to generate a first detection value and a second detection value based on the first detection signals S11 and S12, and the second detection signals S21 and S22. The first detection value is a detection value corresponding to the component of the target magnetic field in a direction parallel to the Y direction. The second detection value is a detection value corresponding to the component of the target magnetic field in a direction parallel to the Z direction. Hereinafter, the first detection value is represented by the symbol Sy, and the second detection value is represented by the symbol Sz.

The processor 2 generates the first and second detection values Sy and Sz as follows, for example. First, the processor 2 generates a value S1 by an arithmetic including obtainment of a difference S11−S12 between the first detection signal S11 and the first detection signal S12, and generates a value S2 by an arithmetic including obtainment of a difference S21−S22 between the second detection signal S21 and the second detection signal S22. Next, the processor 2 calculates values S3 and S4 using the following expressions (1) and (2).

$$S 3 = ( S 2 + S 1 ) / ( 2 cos α ) \qquad ( 1 )$$

$$S 4 = ( S 2 - S 1 ) / ( 2 sin α ) \qquad ( 2 )$$

The first detection value Sy may be the value S3 itself, or may be a result of corrections, such as a gain adjustment and an offset adjustment, made to the value S3. In the same manner, the second detection value Sz may be the value S4 itself, or may be a result of corrections, such as a gain adjustment and an offset adjustment, made to the value S4.

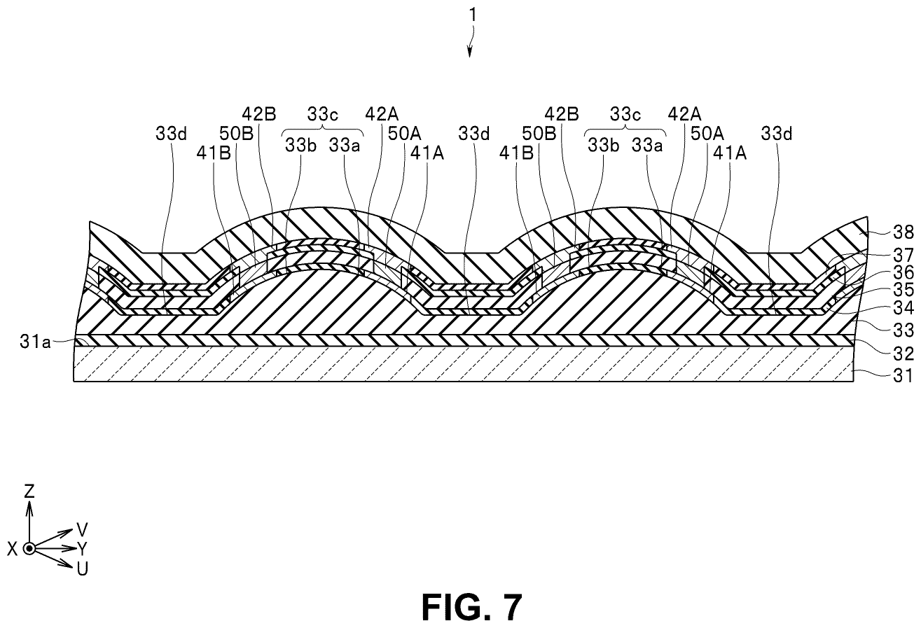

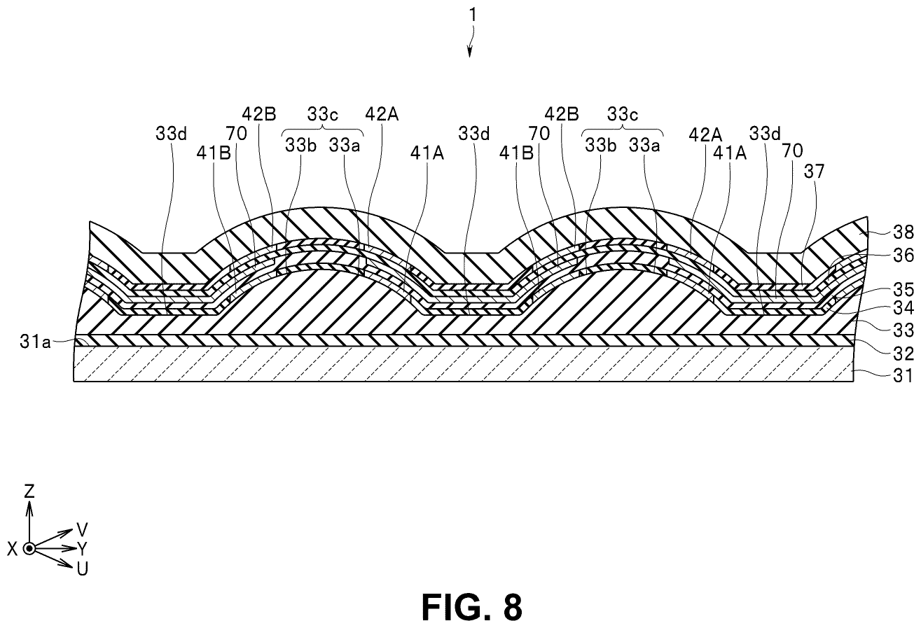

Next, the specific structure of the magnetic sensor 1 will be described in detail with reference to FIGS. 6 through 8. FIG. 6 is a plan view showing a part of the magnetic sensor 1. FIG. 7 shows a part of a cross section at a position indicated by the line 7-7 in FIG. 6. FIG. 8 shows a part of a cross section at a position indicated by the line 8-8 in FIG. 6.

The magnetic sensor 1 includes a substrate 31 having a top surface 31a, insulating layers 32, 33, 34, 35, 36, 37, and 38, a plurality of lower electrodes 41A, a plurality of lower electrodes 41B, a plurality of upper electrodes 42A, and a plurality of upper electrodes 42B. The top surface 31a of the substrate 31 is parallel to an XY plane. The Z direction is also a direction perpendicular to the top surface 31a of the substrate 31. In the example embodiment, the top surface 31a of the substrate 31 may be used as a “reference plane” which is a reference for the dispositions and shapes of the components of the magnetic sensor 1.

The insulating layers 32 and 33 are stacked in this order on the substrate 31. The plurality of lower electrodes 41A and the plurality of lower electrodes 41B are disposed on the insulating layer 33. The insulating layer 34 is disposed, on the insulating layer 33, around the plurality of lower electrodes 41A and around the plurality of lower electrodes 41B. The plurality of first MR elements 50A are disposed on the plurality of lower electrodes 41A. The plurality of second MR elements 50B are disposed on the plurality of lower electrodes 41B. The insulating layer 35 is disposed, on the plurality of lower electrodes 41A, the plurality of lower electrodes 41B, and the insulating layer 34, around the plurality of first MR elements 50A and around the plurality of second MR elements 50B.

The plurality of magnetic field generators 70 are embedded in the insulating layer 35. Each of the plurality of magnetic field generators 70 is disposed at distances from the first MR elements 50A and the lower electrodes 41A, and at distances from the second MR elements 50B and the lower electrodes 41B. The magnetic sensor 1 may further include insulating films interposed between each of the plurality of magnetic field generators 70 and each of the plurality of first MR elements 50A, between each of the plurality of magnetic field generators 70 and each of the plurality of second MR elements 50B, between each of the plurality of magnetic field generators 70 and each of the plurality of lower electrodes 41A, and between each of the plurality of magnetic field generators 70 and each of the plurality of lower electrodes 41B.

The insulating layer 36 is disposed on the insulating layer 35 and the plurality of magnetic field generators 70. In addition, the insulating layer 36 includes a plurality of openings that allow the top surface of the plurality of first MR elements 50A to expose, and a plurality of openings that allow the top surface of the plurality of second MR elements 50B to expose. The plurality of upper electrodes 42A are disposed on the plurality of first MR elements 50A and the insulating layer 36. The plurality of upper electrodes 42B are disposed on the plurality of second MR elements 50B and the insulating layer 36. The insulating layer 37 is disposed, on the insulating layer 36, around the plurality of upper electrodes 42A and around the plurality of upper electrodes 42B. The insulating layer 38 is disposed on the plurality of upper electrodes 42A, the plurality of upper electrodes 42B, and the insulating layer 37.

In the example embodiment, each of the plurality of lower electrodes 41A and the plurality of upper electrodes 42A may be in contact with the first MR elements 50A. Each of the plurality of lower electrodes 41B and the plurality of upper electrodes 42B may be in contact with the second MR elements 50B. The insulating layer 35 may be interposed between the plurality of magnetic field generators 70 and the plurality of lower electrodes 41A and 41B, and may insulate the plurality of magnetic field generators 70 from the plurality of lower electrodes 41A and 41B. The insulating layer 36 may be interposed between the plurality of magnetic field generators 70 and the plurality of upper electrodes 42A and 42B, and may insulate the plurality of magnetic field generators 70 from the plurality of upper electrodes 42A and 42B. The insulating layer 35 may cover a part of each of the plurality of first MR elements 50A and the plurality of second MR elements 50B. The insulating layer 36 may cover a part of each of the plurality of first MR elements 50A and the plurality of second MR elements 50B.

The magnetic sensor 1 includes a support member that supports the plurality of first MR elements 50A and the plurality of second MR elements 50B. The support member includes at least one inclined surface inclined relative to the top surface 31a of the substrate 31. In the example embodiment, in particular, the support member includes an insulating layer 33. The insulating layer 33 is disposed substantially on the top surface 31a of the substrate 31. Note that FIG. 6 shows the insulating layer 33, the plurality of first MR elements 50A, the plurality of second MR elements 50B, and the plurality of magnetic field generators 70, among the components of the magnetic sensor 1.

The insulating layer 33 includes a plurality of protruding surfaces 33c each protruding in a direction (Z direction) away from the top surface 31a of the substrate 31. Each of the plurality of protruding surfaces 33c extends in a direction parallel to the X direction. The overall shape of the protruding surface 33c is a semi-cylindrical curved surface obtained by moving the curved shape (arch shape) of the protruding surface 33c shown in FIGS. 7 and 8 along the direction parallel to the X direction. In addition, the plurality of protruding surfaces 33c are arranged in the direction parallel to the Y direction at specific intervals.

Each of the plurality of protruding surfaces 33c includes an upper end portion farthest from the top surface 31a of the substrate 31. In the example embodiment, the upper end portion of each of the plurality of protruding surfaces 33c is assumed to extend in the direction parallel to the X direction. Herein, focus is placed on a given one protruding surface 33c of the plurality of protruding surfaces 33c. The protruding surface 33c includes a first inclined surface 33a and a second inclined surface 33b. The first inclined surface 33a is a surface of the protruding surface 33c that is on the Y direction side of the protruding surface 33c with respect to the upper end portion of the protruding surface 33c. The second inclined surface 33b is a surface of the protruding surface 33c that is on the −Y direction side of the protruding surface 33c with respect to the upper end portion of the protruding surface 33c. In FIG. 6, the boundary between the first inclined surface 33a and the second inclined surface 33b is indicated by a dotted line.

The upper end portion of the protruding surface 33c may be the boundary between the first inclined surface 33a and the second inclined surface 33b. In such a case, the dotted line shown in FIG. 6 indicates the upper end portion of the protruding surface 33c.

The top surface 31a of the substrate 31 is parallel to the XY plane. The first inclined surface 33a and the second inclined surface 33b are each inclined relative to the top surface 31a of the substrate 31, i.e., the XY plane. In a cross section perpendicular to the top surface 31a of the substrate 31, the distance between the first inclined surface 33a and the second inclined surface 33b becomes small in a direction away from the top surface 31a of the substrate 31.

In the example embodiment, due to the presence of the plurality of protruding surfaces 33c, there are a plurality of first inclined surfaces 33a and a plurality of second inclined surfaces 33b. The insulating layer 33 includes the plurality of first inclined surfaces 33a and the plurality of second inclined surfaces 33b.

The insulating layer 33 further includes a flat surface 33d present around the plurality of protruding surfaces 33c. The flat surface 33d is a surface substantially parallel to the top surface 31a of the substrate 31. The plurality of protruding surfaces 33c each protrude from the flat surface 33d in the Z direction. In the example embodiment, the plurality of protruding surfaces 33c are disposed at intervals. Thus, there exists the flat surface 33d between two protruding surfaces 33c adjacent to each other in the direction parallel to the Y direction.

The insulating layer 33 may include groove portions recessed from the flat surface 33d in the −Z direction. In such a case, the plurality of protruding surfaces 33c may be present in the groove portions.

The plurality of lower electrodes 41A are disposed on the plurality of first inclined surfaces 33a. The plurality of lower electrodes 41B are disposed on the plurality of second inclined surfaces 33b. As described above, since each of the first inclined surfaces 33a and the second inclined surfaces 33b is inclined relative to the reference plane, i.e., the top surface 31a of the substrate 31, the top surface of each of the plurality of lower electrodes 41A and the top surface of each of the plurality of lower electrodes 41B are also inclined relative to the top surface 31a of the substrate 31. Thus, it can be said that the plurality of first MR elements 50A and the plurality of second MR elements 50B are disposed above the inclined surfaces inclined relative to the top surface 31a of the substrate 31. The insulating layer 33 is a member for supporting each of the plurality of first MR elements 50A and the plurality of second MR elements 50B so as to allow each of the first and second MR elements 50A and 50B to be inclined relative to the top surface 31a of the substrate 31.

The plurality of magnetic field generators 70 include a plurality of pairs of magnetic field generators 70, each pair including two magnetic field generators 70. The two magnetic field generators 70 are disposed at a distance from each other in the direction parallel to the X direction with one first MR element 50A and one second MR element 50B interposed therebetween. The two magnetic field generators 70 are each configured to apply a bias magnetic field to the one first MR element 50A and the one second MR element 50B located therebetween. This bias magnetic field includes, as a main component, a component parallel to the X direction.

Each of the plurality of magnetic field generators 70 is disposed above two protruding surfaces 33c adjacent to each other in the direction parallel to the Y direction. Each of the plurality of magnetic field generators 70 is disposed from the first inclined surface 33a of one of the two protruding surfaces 33c to the second inclined surface 33b of the other of the two protruding surfaces 33c. Each of the plurality of magnetic field generators 70 includes a part located above the first inclined surface 33a of the one of the two protruding surfaces 33c, a part located above the second inclined surface 33b of the other of the two protruding surfaces 33c, and a part located above the flat surface 33d interposed between the two protruding surfaces 33c. Furthermore, each of the plurality of magnetic field generators 70 has a bottom surface having a shape along the first inclined surface 33a and the second inclined surface 33b.

As shown in FIG. 6, the plurality of magnetic field generators 70 are aligned so that several magnetic field generators 70 are arranged in rows in both the X and Y directions. Each of the plurality of first MR elements 50A and the plurality of second MR elements 50B is disposed between two magnetic field generators 70 adjacent to each other in the direction parallel to the X direction. Several first MR elements 50A are arranged in a row on one first inclined surface 33a along the direction parallel to the X direction. Several second MR elements 50B are arranged in a row on one second inclined surface 33b along the direction parallel to the X direction.

The rows of the several first MR elements 50A and the rows of the several second MR elements 50B are alternately arranged in the direction parallel to the Y direction.

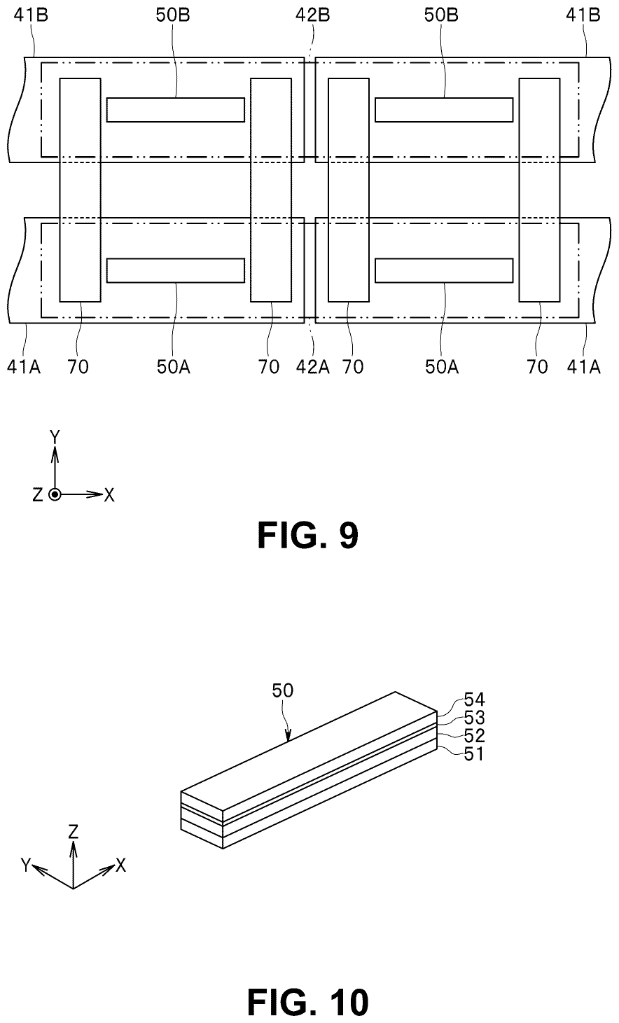

The plurality of first MR elements 50A are connected in series by the plurality of lower electrodes 41A and the plurality of upper electrodes 42A. The plurality of second MR elements 50B are connected in series by the plurality of lower electrodes 41B and the plurality of upper electrodes 42B. Herein, a method for connecting the plurality of first MR elements 50A and a method for connecting the plurality of second MR elements 50B will be described in detail with reference to FIG. 9.

The method for connecting the plurality of first MR elements 50A will now be described. As shown in FIG. 9, each lower electrode 41A has a long slender shape. Two lower electrodes 41A adjacent to each other in the longitudinal direction of the lower electrodes 41A have a gap therebetween. The first MR elements 50A are disposed, on the top surface of each lower electrode 41A, near both ends in the longitudinal direction. Each upper electrode 42A has a long slender shape, and electrically connects two adjacent first MR elements 50A that are disposed respectively on two lower electrodes 41A adjacent to each other in the longitudinal direction of the lower electrodes 41A.

Although not shown in the drawings, one first MR element 50A located at the end of a row of several first MR elements 50A is connected to another first MR element 50A located at the end of another row of several first MR elements 50A that are adjacent to one another in a direction intersecting the longitudinal direction of the lower electrodes 41A. Such two first MR elements 50A are connected to each other by a not-shown electrode. The not-shown electrode may be an electrode connecting the bottom surfaces or the top surfaces of the two first MR elements 50A.

The foregoing description of the method for connecting the plurality of first MR elements 50A also applies to the method for connecting the plurality of second MR elements 50B. In the above description, if the first MR elements 50A, the lower electrodes 41A, and the upper electrodes 42A are replaced respectively with the second MR elements 50B, the lower electrodes 41B, and the upper electrodes 42B, the method for connecting the plurality of second MR elements 50B is described.

Note that FIG. 9 shows an example in which two magnetic field generators 70 are disposed at positions that are between the two first MR elements 50A and that are between the two second MR elements 50B. However, one magnetic field generator 70 may be disposed at a position that is between the two first MR elements 50A and that is between the two second MR elements 50B. In addition, FIG. 9 shows an example in which the magnetic field generators 70 overlap the lower electrodes 41A and 41B when viewed in the Z direction. However, the magnetic field generators 70 do not have to overlap the lower electrodes 41A and 41B when viewed in the Z direction.

Next, a configuration of the MR element 50 will be described in more detail with reference to FIG. 10. In FIG. 10, the reference numeral 52 denotes the magnetization pinned layer, the reference numeral 53 the gap layer, and the reference numeral 54 the free layer. The MR element 50 further includes an antiferromagnetic layer 51. The antiferromagnetic layer 51, the magnetization pinned layer 52, the gap layer 53, and the free layer 54 are stacked in this order from the lower electrode 41A (lower electrode 41B) to the upper electrode 42A (upper electrode 42B). The antiferromagnetic layer 51 is formed of an antiferromagnetic material, and is exchange-coupled with the magnetization pinned layer 52 to thereby fix the magnetization direction of the magnetization pinned layer 52. Note that the magnetization pinned layer 52 may be a so-called self-pinned layer (Synthetic Ferri Pinned layer, SFP layer). The self-pinned layer has a stacked ferri-structure in which a ferromagnetic layer, a nonmagnetic intermediate layer, and a ferromagnetic layer are stacked, and the two ferromagnetic layers are antiferromagnetically coupled. In a case where the magnetization pinned layer 52 is the self-pinned layer, the antiferromagnetic layer 51 may be omitted.

Note that the layers 51 to 54 of each MR element 50 may be stacked in the reverse order to that shown in FIG. 10.

In the first MR element 50A, the antiferromagnetic layer 51, the magnetization pinned layer 52, the gap layer 53, and the free layer 54 are stacked in a direction intersecting the first inclined surface 33a (see FIGS. 6 and 7). This direction may be a direction perpendicular to the first inclined surface 33a.

In the second MR element 50B, the antiferromagnetic layer 51, the magnetization pinned layer 52, the gap layer 53, and the free layer 54 are stacked in a direction intersecting the second inclined surface 33b (see FIGS. 6 and 7). This direction may be a direction perpendicular to the second inclined surface 33b.

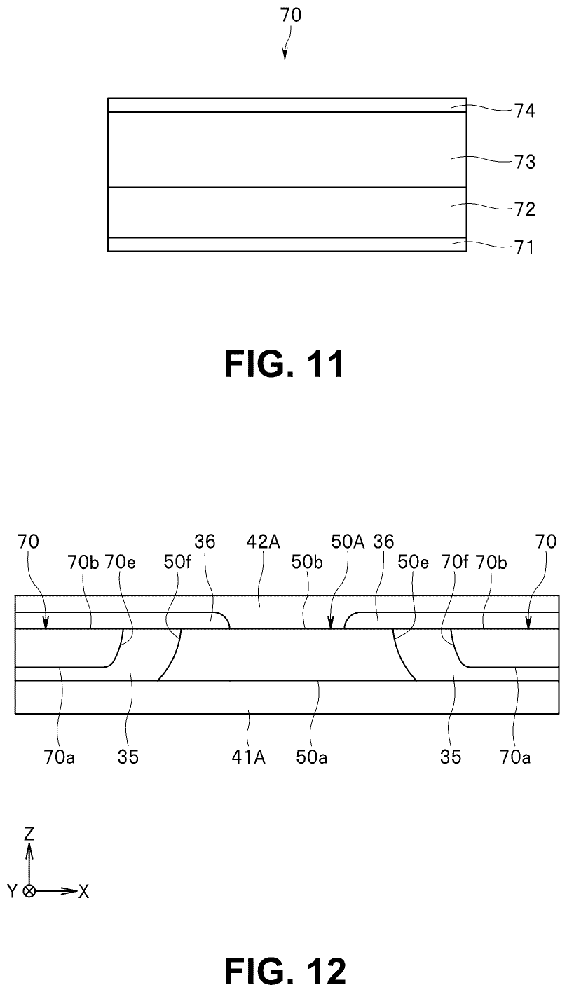

Next, a configuration of the magnetic field generator 70 will be described with reference to FIG. 11. FIG. 11 is a side view showing the magnetic field generator 70. The magnetic field generator 70 includes a ferromagnetic portion 73 and an antiferromagnetic portion 72 that is in contact with the ferromagnetic portion 73 and is exchange-coupled with the ferromagnetic portion 73.

The ferromagnetic portion 73 has its overall magnetization. The overall magnetization of the ferromagnetic portion 73 refers to the volume average of the vector sum of magnetic moments in units of atoms, crystal lattices, or the like in the entire ferromagnetic portion 73. Hereinafter, the overall magnetization of the ferromagnetic portion 73 will simply be referred to as the magnetization of the ferromagnetic portion 73.

In the magnetic field generator 70, the magnetization direction of the ferromagnetic portion 73 is defined by exchange coupling between the antiferromagnetic portion 72 and the ferromagnetic portion 73. The ferromagnetic portion 73 and the antiferromagnetic portion 72 generate a bias magnetic field to be applied to the MR element 50, based on the magnetization of the ferromagnetic portion 73. The magnetic field generator 70 thus constituted is highly resistant to disturbance magnetic fields.

The ferromagnetic portion 73 is formed of a ferromagnetic material containing one or more elements selected from the group consisting of Co, Fe, and Ni. Examples of such a ferromagnetic material include CoFe, CoFeB, and CoNiFe. The antiferromagnetic portion 72 is formed of an antiferromagnetic material such as IrMn or PtMn.

The magnetic field generator 70 further includes a buffer layer 71 and a cap layer 74. The buffer layer 71, the antiferromagnetic portion 72, the ferromagnetic portion 73, and the cap layer 74 are stacked in this order. Each of the buffer layer 71 and the cap layer 74 is formed of a nonmagnetic metallic material such as, for example, Ru, Ta, Cu, or Cr.

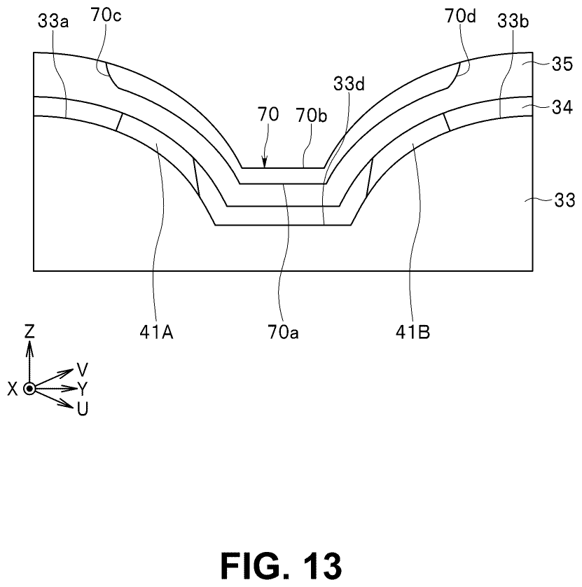

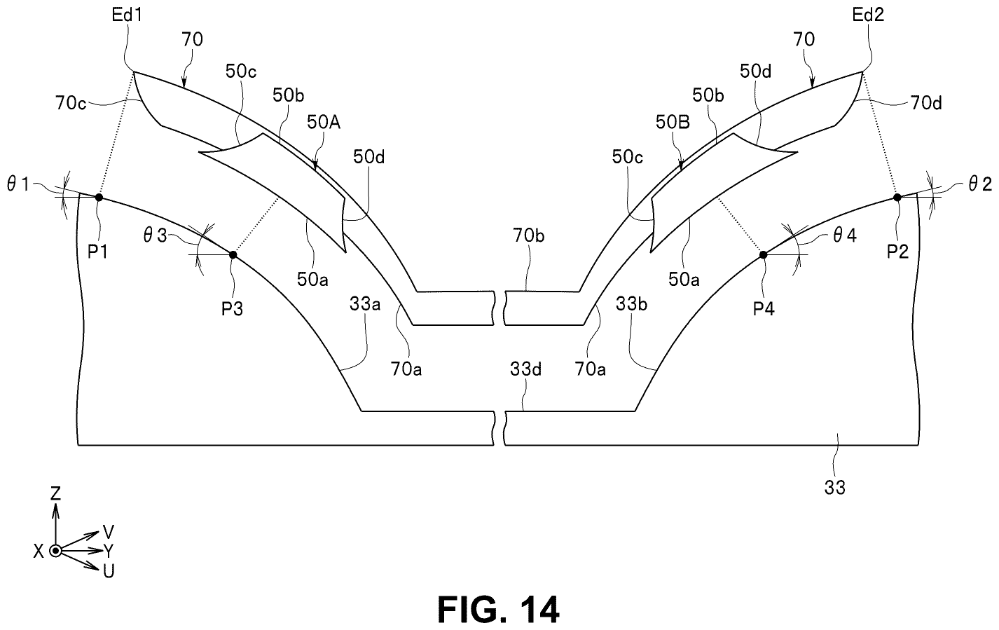

Next, features of the shapes and dispositions of the MR element 50 and the magnetic field generator 70 will be described with reference to FIGS. 6 through 9, and 12 through 14. FIGS. 12 and 13 are each a cross-sectional view showing a part of the magnetic sensor 1. FIG. 12 shows a cross section that is parallel to the XZ plane and is perpendicular to the top surface 31a of the substrate 31, and that intersects the first MR element 50A and the magnetic field generator 70. FIG. 13 shows a cross section that is parallel to a YZ plane and is perpendicular to the top surface 31a of the substrate 31, and that intersects the magnetic field generator 70. Note that the cross section shown in FIG. 13 corresponds to a “second cross section” in the disclosure. FIG. 14 is an explanatory diagram for describing a shape of the side surface of the magnetic field generator 70.

Hereinafter, even when descriptions are made with reference to FIG. 12, features common to the first MR element 50A and the second MR element 50B will be described as features of the MR element 50.

The magnetic field generator 70 is disposed at a distance from the MR element 50. The insulating layer 35 is interposed between the MR element 50 and the magnetic field generator 70.

The dimension of the magnetic field generator 70 in the direction parallel to the Y direction is greater than that of the MR element 50 in the direction parallel to the Y direction. When viewed in the X direction, at least a part of the MR element 50 overlaps the magnetic field generator 70. In the example embodiment, in particular, when viewed in the X direction, at least a part of the free layer 54 of the MR element 50 may overlap the ferromagnetic portion 73 of the magnetic field generator 70.

The MR element 50 includes a bottom surface 50a facing the first inclined surface 33a or the second inclined surface 33b, a top surface 50b opposite the bottom surface 50a, and four side surfaces connecting the bottom surface 50a and the top surface 50b.

The side surface 50c is located at the end of the MR element 50 in the −Y direction. The side surface 50d is located at the end of the MR element 50 in the Y direction. The side surface 50e is located at the end of the MR element 50 in the X direction. The side surface 50f is located at the end of the MR element 50 in the −X direction.

As shown in FIG. 12, each of the side surfaces 50e and 50f of the MR element 50 is inclined relative to the top surface 31a of the substrate 31. In one MR element 50, the distance between the side surface 50e and the side surface 50f in the direction parallel to the X direction decreases with increasing distance from the top surface 31a of the substrate 31. Each of the side surfaces 50c and 50d of the MR element 50 is inclined relative to the top surface 31a of the substrate 31. In the first MR element 50A, the distance between the side surface 50c and the side surface 50d decreases with increasing distance from the first inclined surface 33a. In the second MR element 50B, the distance between the side surface 50c and the side surface 50d decreases with increasing distance from the second inclined surface 33b.

The magnetic field generator 70 includes a bottom surface 70a facing the support member, a top surface 70b opposite the bottom surface 70a, and four side surfaces 70c, 70d, 70e, and 70f that connect the bottom surface 70a and the top surface 70b. The side surface 70c is located at the end of the magnetic field generator 70 in the −Y direction. Furthermore, the side surface 70c is located above the first inclined surface 33a. The side surface 70d is located at the end of the magnetic field generator 70 in the Y direction. In addition, the side surface 70d is located above the second inclined surface 33b. The side surface 70e is located at the end of the magnetic field generator 70 in the X direction. The side surface 70f is located at the end of the magnetic field generator 70 in the −X direction.

As shown in FIG. 12, each of the side surfaces 70e and 70f of the magnetic field generator 70 is inclined relative to the top surface 31a of the substrate 31. In one magnetic field generator 70, the distance between the side surface 70e and the side surface 70f in the direction parallel to the X direction increases with increasing distance from the top surface 31a of the substrate 31. As shown in FIG. 13, each of the side surfaces 70c and 70d of the magnetic field generator 70 is inclined relative to the top surface 31a of the substrate 31. In one magnetic field generator 70, the distance between the side surface 70c and the side surface 70d in the direction parallel to the Y direction increases with increasing distance from the top surface 31a of the substrate 31.

The magnetic field generator 70 may have a first end portion Ed1 and a second end portion Ed2 located at both ends of the magnetic field generator 70 in the direction parallel to the Y direction. The first end portion Ed1 is located at a position where the top surface 70b and the side surface 70c of the magnetic field generator 70 intersect with each other. Furthermore, the first end portion Ed1 is located above the first inclined surface 33a. The second end portion Ed2 is located at a position where the top surface 70b and the side surface 70d of the magnetic field generator 70 intersect with each other. Furthermore, the second end portion Ed2 is located above the second inclined surface 33b. The top surface 70b connects the first end portion Ed1 and the second end portion Ed2.

The distance from the top surface 31a of the substrate 31 to the first end portion Ed1 may be equal to or different from the distance from the top surface 31a of the substrate 31 to the second end portion Ed2. In the example embodiment, the distance from the top surface 31a of the substrate 31 to the first end portion Ed1 is equal to or substantially equal to the distance from the top surface 31a of the substrate 31 to the second end portion Ed2.

In the example embodiment, an angle that the protruding surface 33c forms with respect to the top surface 31a of the substrate 31 at a given position on the protruding surface 33c changes with the distance from the top surface 31a of the substrate 31 to the given position. Here, the angle that the protruding surface 33c forms with respect to the top surface 31a of the substrate 31 is represented by the symbol θ. The angle θ is 0° or more and 90° or less. In addition, a position on the protruding surface 33c, which is closest to the first end portion Ed1, is referred to as a first position P1, a position on the protruding surface 33c, which is closest to the second end portion Ed2, is referred to as a second position P2, a given position on the protruding surface 33c (first inclined surface 33a) which overlaps the first MR element 50A when viewed in the Z direction is referred to as a third position P3, and a given position on the protruding surface 33c (second inclined surface 33b) which overlaps the second MR element 50B when viewed in the Z direction is referred to as a fourth position P4. The angle θ at the first position P1 is represented by the symbol θ1, the angle θ at the second position P2 by the symbol θ2, the angle θ at the third position P3 by the symbol θ3, and the angle θ at the fourth position P4 by the symbol θ4.

Each of the angles θ1 and θ2 in the YZ cross section intersecting the magnetic field generator 70 may be smaller than the angles θ3 and θ4 in the YZ cross section intersecting the MR element 50. Each of the angles θ1 and θ2 may be within a range from 0°to 40°, for example, as long as the requirement that each of the angles θ1 and θ2 is smaller than the angles θ3 and θ4 is satisfied.

Next, a manufacturing method of the magnetic sensor 1 in the example embodiment will be briefly described. The process of manufacturing the magnetic sensor 1 includes a process of forming the insulating layer 33 as the support member, a process of forming a plurality of MR elements 50, and a process of forming the plurality of magnetic field generators 70. The plurality of MR elements 50 and the plurality of magnetic field generators 70 are formed on the insulating layer 33.

Initially, the process of forming the plurality of MR elements 50 will be described. In the process of forming the plurality of MR elements 50, first, a plurality of initial MR elements to later become the plurality of MR elements 50 are formed. Each of the plurality of initial MR elements includes an initial magnetization pinned layer to later become the magnetization pinned layer 52, the antiferromagnetic layer 51, the gap layer 53, and the free layer 54.

Next, the magnetization direction of the initial magnetization pinned layer is fixed using laser light and an external magnetic field including a component in a specific direction. For example, in the plurality of initial MR elements to later become the plurality of first MR elements 50A constituting the resistor sections R11 and R13 of the first detection circuit 10, the plurality of initial MR elements are irradiated with laser light while an external magnetic field in the Y direction is applied thereto. The irradiation of the laser light is performed so that the temperature of the plurality of initial MR elements irradiated with the laser light becomes equal to or higher than a blocking temperature of the antiferromagnetic layer 51. The temperature of the plurality of initial MR elements can be adjusted, for example, by the intensity and the pulse width of the laser light.

The external magnetic field in the Y direction can be divided into a component in the U direction and a component in a direction orthogonal to the U direction. After the irradiation of the laser light, when the temperature of the plurality of initial MR elements becomes lower than the blocking temperature, the magnetization directions of the initial magnetization pinned layers are fixed in the U direction. This causes the initial magnetization pinned layers to become the magnetization pinned layers 52, and the initial MR elements to become the first MR elements 50A.

In the plurality of initial MR elements to later become the plurality of first MR elements 50A constituting the resistor sections R12 and R14 of the first detection circuit 10, the magnetization direction of the initial magnetization pinned layer of each of the plurality of initial MR elements can be fixed in the −U direction by using an external magnetic field in the −Y direction. The plurality of first MR elements 50A are thus formed. The magnetization direction of the magnetization pinned layer 52 of each of the plurality of second MR elements 50B constituting each of the resistor sections R21 to R24 of the second detection circuit 20 is also fixed by the same method as with the magnetization pinned layer 52 of each of the plurality of first MR elements 50A.

The MR element 50 is completed by patterning a stacked film by etching so that the side surface of the MR element 50 is formed on the stacked film, after the magnetization direction of the magnetization pinned layer 52 is fixed. Note that the process of fixing the magnetization directions of the initial magnetization pinned layers may be performed after the side surface of the MR element 50 is formed on the stacked film. Next, the insulating layer 35 is formed around the plurality of first MR elements 50A and around the plurality of second MR elements 50B.

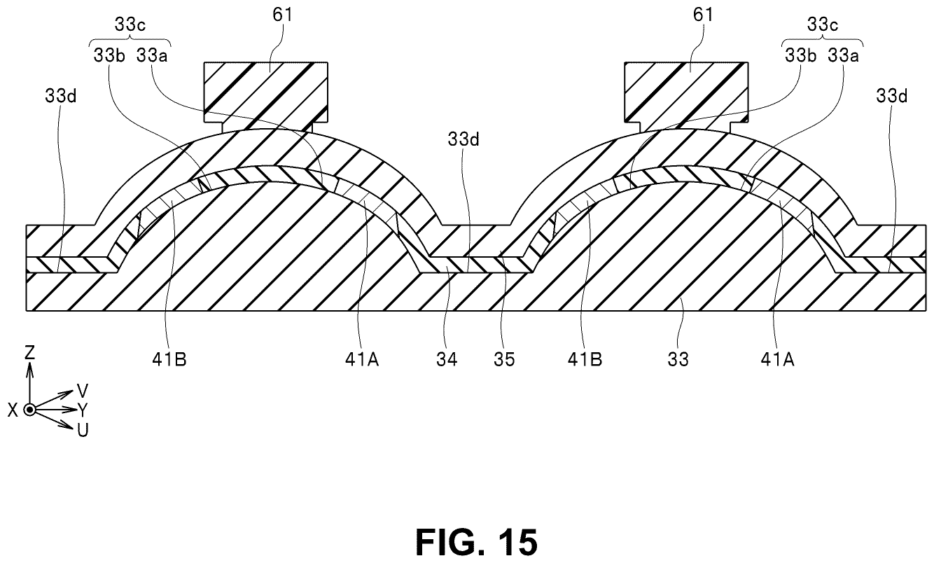

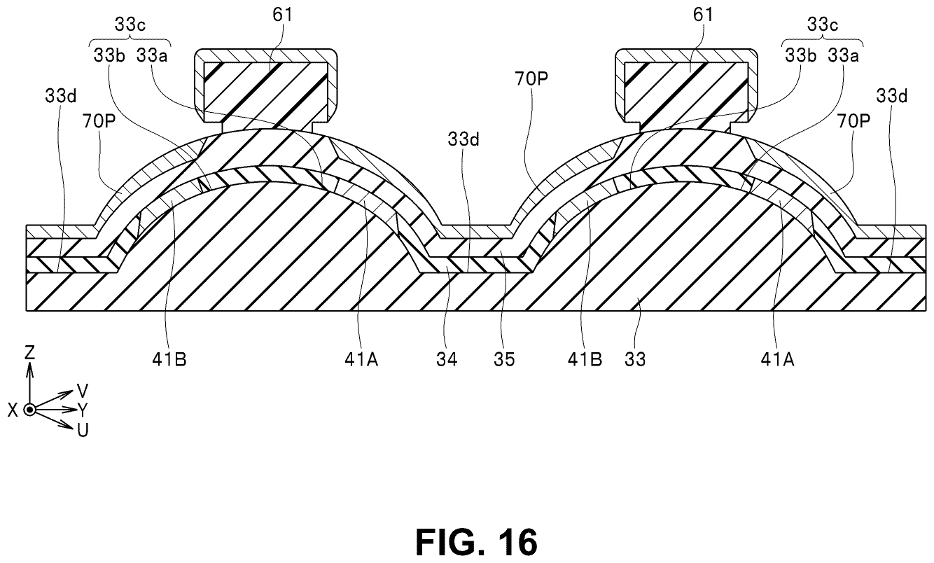

Next, the process of forming the plurality of magnetic field generators 70 will be described with reference to FIGS. 15 and 16. FIGS. 15 and 16 each show a stack in the manufacturing process of the magnetic sensor 1. The process of forming the plurality of magnetic field generators 70 may be performed after the plurality of MR elements 50 and the insulating layer 35 are formed.

In the process of forming the plurality of magnetic field generators 70, first, a plurality of photoresist masks 61 are formed on the MR element 50 and the insulating layer 35, as shown in FIG. 15. The plurality of photoresist masks 61 are formed by patterning a photoresist layer applied on the MR element 50 and the insulating layer 35. Each of the plurality of photoresist masks 61 is formed on the protruding surface 33c, but is not formed on the flat surface 33d. Next, using the plurality of photoresist masks 61 as etching masks, the insulating layer 35 is etched by ion milling, for example, so that a plurality of groove portions are formed in the insulating layer 35. The plurality of groove portions have a shape corresponding to the plurality of magnetic field generators 70.

Next, as shown in FIG. 16, a plurality of initial magnetic field generators 70P are formed so that the plurality of initial magnetic field generators 70P to later become the magnetic field generators 70 are housed within the plurality of groove portions, leaving the plurality of photoresist masks 61 in place. Each of the plurality of initial magnetic field generators 70P at least includes an initial ferromagnetic portion to later become the ferromagnetic portion 73, and the antiferromagnetic portion 72. Next, the plurality of photoresist masks 61 are removed.

Next, the magnetization direction of the initial ferromagnetic portion is fixed using laser light and an external magnetic field including a component in a specific direction. The method of fixing the magnetization direction of the initial ferromagnetic portion is the same as the method of fixing the magnetization direction of the initial magnetization pinned layer. In other words, each of the plurality of initial magnetic field generators 70P is irradiated with laser light while an external magnetic field is applied thereto. The irradiation of the laser light is performed so that the temperature of the plurality of initial magnetic field generators 70P irradiated with the laser light becomes equal to or higher than a blocking temperature of the antiferromagnetic portion 72. The temperature of the plurality of initial magnetic field generators 70P can be adjusted, for example, by the intensity and the pulse width of the laser light. After the irradiation of the laser light, when the temperature of the plurality of initial magnetic field generators 70P becomes lower than the blocking temperature, the magnetization direction of the initial ferromagnetic portion is fixed in the above-described specific direction. This causes the initial ferromagnetic portion to become the ferromagnetic portion 73, and the plurality of initial magnetic field generators 70P to become the plurality of magnetic field generators 70.

For example, in the plurality of initial magnetic field generators 70P to later become the plurality of magnetic field generators 70 each of which apply a bias magnetic field to the plurality of first MR elements 50A constituting the resistor sections R11 and R12 of the first detection circuit 10 and the plurality of second MR elements 50B constituting the resistor sections R21 and R22 of the second detection circuit 20, the magnetization directions of the initial ferromagnetic portions are fixed in the X direction by irradiating the plurality of initial magnetic field generators 70P with laser light while an external magnetic field in the X direction is applied thereto. This causes the initial ferromagnetic portions to become the ferromagnetic portions 73, and the initial magnetic field generators 70P to become the magnetic field generators 70. In the plurality of initial magnetic field generators 70P to later become the plurality of magnetic field generators 70 each of which apply a bias magnetic field to the plurality of first MR elements 50A constituting the resistor sections R13 and R14 of the first detection circuit 10 and the plurality of second MR elements 50B constituting the resistor sections R23 and R24 of the second detection circuit 20, the magnetization direction of the initial ferromagnetic portion of each of the plurality of initial magnetic field generators 70P can be fixed in the −X direction by using an external magnetic field in the −X direction. The plurality of magnetic field generators 70 are thus formed.

Note that the intensity of the laser light used to fix the magnetization directions of the initial ferromagnetic portions may be smaller than the intensity of the laser light used to fix the magnetization directions of the initial magnetization pinned layers. The intensity of the laser light used to fix the magnetization directions of the initial ferromagnetic portions may be an intensity such that the change in magnetoresistive change rate, which is the ratio of the magnetoresistive change to the resistance of the MR element 50, is suppressed.

Next, effects of the magnetic sensor 1 according to the example embodiment will be described. In the example embodiment, the magnetic field generator 70 is formed from the first inclined surface 33a to the second inclined surface 33b. The angle θ that the protruding surface 33c forms with respect to the top surface 31a of the substrate 31 at a given position on the protruding surface 33c including the first and second inclined surfaces 33a and 33b changes with the distance from the top surface 31a of the substrate 31 to the given position. In the example embodiment, in particular, the angle θ becomes greater with decreasing distance from the top surface 31a of the substrate 31 to the given position.

Here, a magnetic field generator of a comparative example, which is formed to be disposed above only one of the first inclined surface 33a or the second inclined surface 33b of the protruding surface 33c, will be considered. The magnetic field generator of the comparative example has a first side surface and a second side surface located at both ends of the magnetic field generator in the direction parallel to the Y direction. The first side surface and the second side surface are located at positions different from each other in the direction parallel to the Z direction. The distance from the top surface 31a of the substrate 31 to the first side surface is greater than the distance from the top surface 31a of the substrate 31 to the second side surface.

The magnetic field generator of the comparative example is formed by using a plurality of photoresist masks similarly as the magnetic field generator in the example embodiment. As described above, the plurality of photoresist masks are formed by patterning the photoresist layer applied onto the MR element 50 and the insulating layer 35. The photoresist layer is formed on the protruding surface 33c and the flat surface 33d. The thickness of the photoresist layer increases on the flat surface 33d and decreases in a direction away from the flat surface 33d (direction closer to the upper end portion of the protruding surface 33c).

Each of the plurality of photoresist masks has a first end portion corresponding to the first side surface and a second end portion corresponding to the second side surface. If the position of each of the first and second end portions changes due to manufacturing variation, the thickness of the photoresist mask in the vicinity of the first end portion and the thickness of the photoresist mask in the vicinity of the second end portion change. When the insulating layer 35 is etched by ion milling, if the thickness of the photoresist mask changes, the length of the shadow of the photoresist mask extending from each of the first and second end portions changes. As a result, the angle that the wall surface of the groove portion formed in the insulating layer 35 forms with respect to the protruding surface 33c changes, and as a result, the angle that the first side surface forms with respect to the protruding surface 33c and the angle that the second side surface forms with respect to the protruding surface 33c change. In the magnetic field generator of the comparative example, in particular, the first side surface and the second side surface are located at positions different from each other in the direction parallel to the Z direction. Therefore, when the position of each of the first and second end portions changes, an amount of the change in the thickness of the photoresist mask in the vicinity of the first end portion and an amount of the change in the thickness of the photoresist mask in the vicinity of the second end portion are different from each other due to a difference in the thicknesses of the photoresist layer. As a result, an amount of the change in the angle that the first side surface forms with respect to the protruding surface 33c and an amount of the change in the angle that the second side surface forms with respect to the protruding surface 33c are different from each other.

When the angle that the first side surface forms with respect to the protruding surface 33c varies, a diamagnetic field in the vicinity of the first side surface varies. Similarly, when the angle that the second side surface forms with respect to the protruding surface 33c varies, a diamagnetic field in the vicinity of the second side surface varies. Due to the variations in these diamagnetic fields, the shape magnetic anisotropy of the magnetic field generator in the direction (direction in which the magnetic field generator and the MR element 50 are arranged) which is parallel to the X direction is affected. As a result, a variation occurs when the magnetization direction of the initial ferromagnetic portion is fixed by using laser light. The magnetic field generator of the comparative example, in particular, has a problem that, due to the difference between the amount of the change in the angle that the first side surface forms with respect to the protruding surface 33c and the amount of the change in the angle that the second side surface forms with respect to the protruding surface 33c, the strength of the bias magnetic field to be applied to the MR element 50 varies, which results in a variation of the characteristic of the magnetic sensor.

In contrast, in the example embodiment, the magnetic field generator 70 is formed from the first inclined surface 33a to the second inclined surface 33b. With such a configuration, according to the example embodiment, the position of the first end portion Ed1 in the direction parallel to the Z direction and the position of the second end portion Ed2 in the direction parallel to the Z direction can be made the same or substantially the same, and the position of the side surface 70c in the direction parallel to the Z direction and the position of the side surface 70d in the direction parallel to the Z direction can be made the same or substantially the same. With such a configuration, according to the example embodiment, the angle that the side surface 70c forms with respect to the first inclined surface 33a and the angle that the side surface 70d forms with respect to the second inclined surface 33b can be made the same or substantially the same. As a result, according to the example embodiment, the variation in the strength of the bias magnetic field to be applied to the first MR element 50A and the strength of the bias magnetic field to be applied to the second MR element 50B can be suppressed.

In the example embodiment, in particular, the side surfaces 70c and 70d are disposed above the position close to the upper end portion of the protruding surface 33c. The angle θ at the position close to the upper end portion of the protruding surface 33c is smaller than the angle at the position close to the flat surface 33d of the protruding surface 33c. Therefore, according to the example embodiment, it is possible to suppress the change in the angle that the side surface 70c forms with respect to the first inclined surface 33a due to the variation in the position of the side surface 70c, and also suppress the change in the angle that the side surface 70d forms with respect to the second inclined surface 33b due to the variation in the position of the side surface 70d. As a result, according to the example embodiment, it is possible to suppress the variations in the strength of the bias magnetic field to be applied to the first MR element 50A and in the strength of the bias magnetic field to be applied to the second MR element 50B.

### Modification Examples

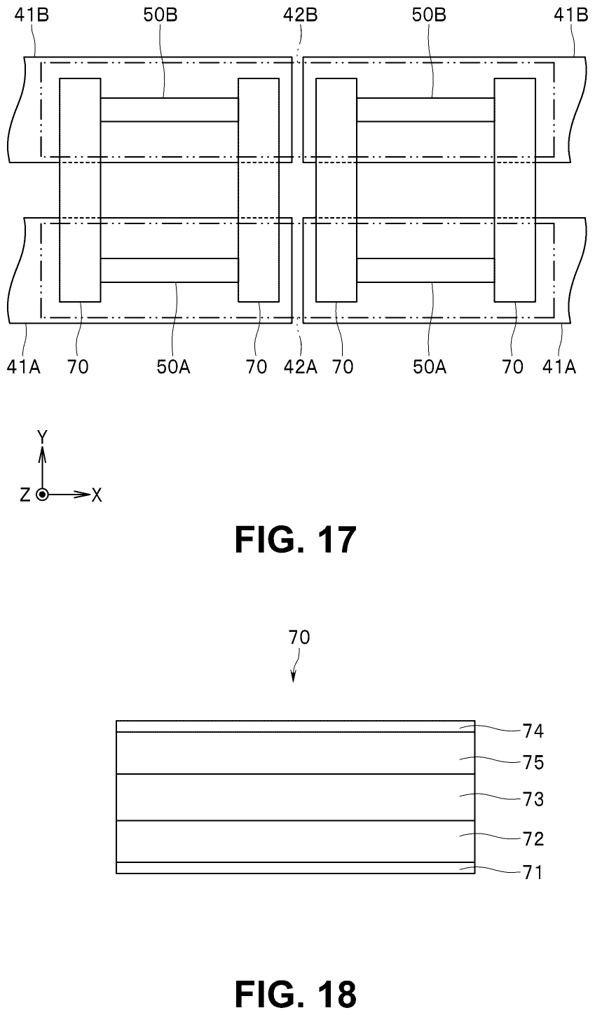

Next, first through seventh modification examples of the magnetic sensor 1 according to the example embodiment will be described. Initially, the first modification example will be described with reference to FIG. 17. FIG. 17 is a plan view showing first MR elements 50A, second MR elements 50B, magnetic field generators 70, lower electrodes 41A and 41B, and upper electrodes 42A and 42B, of the first modification example. In the first modification example, instead of the insulating layer 35, an insulating film, a part of which is formed along the side surface of the first MR element 50A and another part of which is formed along the side surface of the second MR element 50B, is interposed between the first MR element 50A and the magnetic field generator 70, and between the second MR element 50B and the magnetic field generator 70. When viewed in the Z direction, a part of the magnetic field generator 70 overlaps a part of each of the first MR element 50A and the second MR element 50B.

Next, the second modification example will be described with reference to FIG. 18. FIG. 18 is a side view showing a magnetic field generator 70 of the second modification example. In the second modification example, the magnetic field generator 70 further includes an antiferromagnetic portion 75. The antiferromagnetic portion 75 is disposed between a ferromagnetic portion 73 and a cap layer 74. The antiferromagnetic portion 75 is formed of an antiferromagnetic material such as IrMn or PtMn. In the magnetic field generator 70 of the second modification example, the magnetization direction of the ferromagnetic portion 73 is defined by the antiferromagnetic portion 72 and the antiferromagnetic portion 75 being exchange-coupled with the ferromagnetic portion 73.

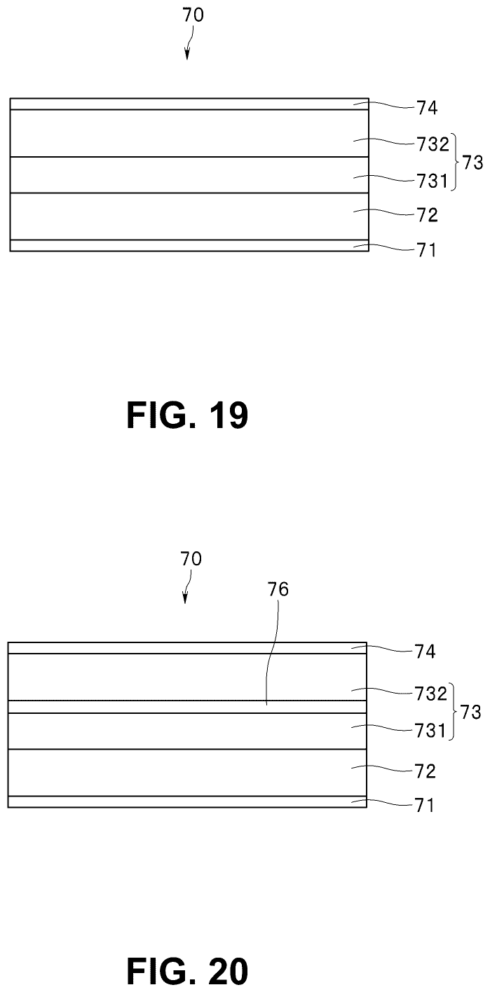

Next, the third modification example will be described with reference to FIG. 19. FIG. 19 is a side view showing a magnetic field generator 70 of the third modification example. In the third modification example, a ferromagnetic portion 73 of the magnetic field generator 70 includes a ferromagnetic layer 731 and a ferromagnetic layer 732. A buffer layer 71, an antiferromagnetic portion 72, the ferromagnetic layer 731, the ferromagnetic layer 732, and a cap layer 74 are stacked in this order. The ferromagnetic layers 731 and 732 are each formed of a ferromagnetic material containing one or more elements selected from the group consisting of Co, Fe, and Ni. In the third modification example, the ferromagnetic layer 731 and the ferromagnetic layer 732 each have magnetization in the same direction.

In the third modification example, the ferromagnetic layer 731 may be formed of a ferromagnetic material that can increase the exchange coupling energy between the ferromagnetic layer 731 and the antiferromagnetic portion 72, and the ferromagnetic layer 732 may be formed of a ferromagnetic material having a saturation magnetic flux density greater than that of the ferromagnetic material constituting the ferromagnetic layer 731. In such a case, the strength of the bias magnetic field generated by the magnetic field generator 70 can be increased, while increasing the exchange coupling energy between the ferromagnetic portion 73 including the ferromagnetic layers 731 and 732 and the antiferromagnetic portion 72, and the magnetic field generator 70 can be made smaller in size. An example of the ferromagnetic layer 731 includes a Co₇₀Fe₃₀ layer. An example of the ferromagnetic layer 732 includes a Co₃₀Fe₇₀ layer. Note that Co₇₀Fe₃₀ represents an alloy containing 70 atomic percent Co and 30 atomic percent Fe, and Co₃₀Fe₇₀ represents an alloy containing 30 atomic percent Co and 70 atomic percent Fe.

Next, the fourth modification example will be described with reference to FIG. 20. FIG. 20 is a side view showing a magnetic field generator 70 of the fourth modification example. In the fourth modification example, a ferromagnetic portion 73 of the magnetic field generator 70 includes a ferromagnetic layer 731 and a ferromagnetic layer 732. The magnetic field generator 70 further includes a nonmagnetic layer 76. A buffer layer 71, an antiferromagnetic portion 72, the ferromagnetic layer 731, a nonmagnetic layer 76, the ferromagnetic layer 732, and a cap layer 74 are stacked in this order. The ferromagnetic layers 731 and 732 are each formed of a ferromagnetic material containing one or more elements selected from the group consisting of Co, Fe, and Ni. The ferromagnetic layer 731 and the ferromagnetic layer 732 may be formed of the same ferromagnetic material or different ferromagnetic materials. The nonmagnetic layer 76 is formed of a nonmagnetic metallic material such as, for example, Ru.

In the fourth modification example, the ferromagnetic layer 731 and the ferromagnetic layer 732 may be ferromagnetically exchange-coupled with each other via the nonmagnetic layer 76 so as to have the same magnetization direction. In such a case, the ferromagnetic layer 731 and the ferromagnetic layer 732 have the magnetization in the same direction. The thickness of the nonmagnetic layer 76 is set to a thickness so as not to lose the exchange coupling between the ferromagnetic layer 731 and the ferromagnetic layer 732. By providing the nonmagnetic layer 76, it is possible to adjust the coercivity of the ferromagnetic portion 73 and to adjust the surface roughness of the base of the ferromagnetic layer 732.

Alternatively, the ferromagnetic layer 731 and the ferromagnetic layer 732 may be antiferromagnetically exchange-coupled with each other via the nonmagnetic layer 76 by the RKKY interaction. In such a case, the magnetization direction of the ferromagnetic layer 731 and the magnetization direction of the ferromagnetic layer 732 are opposite to each other. The magnetization direction of the ferromagnetic portion 73 is the same as the magnetization direction of the ferromagnetic layer 731. When the ferromagnetic layer 731 and the ferromagnetic layer 732 are antiferromagnetically exchange-coupled with each other, the net moment of the ferromagnetic portion 73 becomes small. Therefore, in the ferromagnetic portion 73, the Zeeman energy, which is the energy produced by the external magnetic field acting on the magnetic moment, becomes small. As a result, even when an external magnetic field is applied, the magnetization direction of the ferromagnetic portion 73 is less likely to incline than when the Zeeman energy is large.

The thickness of the nonmagnetic layer 76 is set so that the respective magnetization directions of the ferromagnetic layer 731 and the ferromagnetic layer 732 due to the RKKY interaction become expected directions, and the strength of the exchange coupling by the RKKY interaction becomes an expected strength.

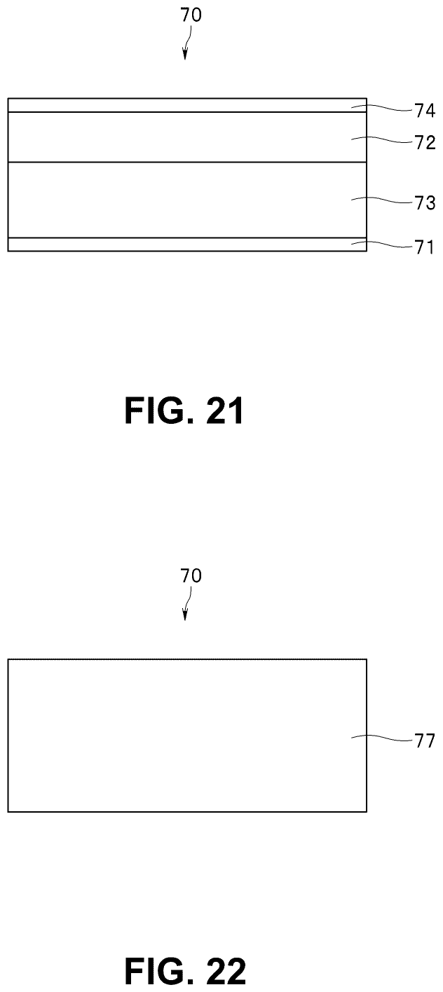

Next, the fifth modification example will be described with reference to FIG. 21. FIG. 21 is a side view showing a magnetic field generator 70 of the fifth modification example. In the fifth modification example, a buffer layer 71, an antiferromagnetic portion 72, a ferromagnetic portion 73, and a cap layer 74 of the magnetic field generator 70 are stacked in the order of the buffer layer 71, the ferromagnetic portion 73, the antiferromagnetic portion 72, and the cap layer 74.

Next, the sixth modification example will be described with reference to FIG. 22. FIG. 22 is a side view showing a magnetic field generator 70 of the sixth modification example. In the sixth modification example, the magnetic field generator 70 includes a magnet 77 formed of a hard magnetic material, instead of the antiferromagnetic portion 72 and the ferromagnetic portion 73. The magnetic field generator 70 may include or does not have to include a buffer layer 71 and a cap layer 74.

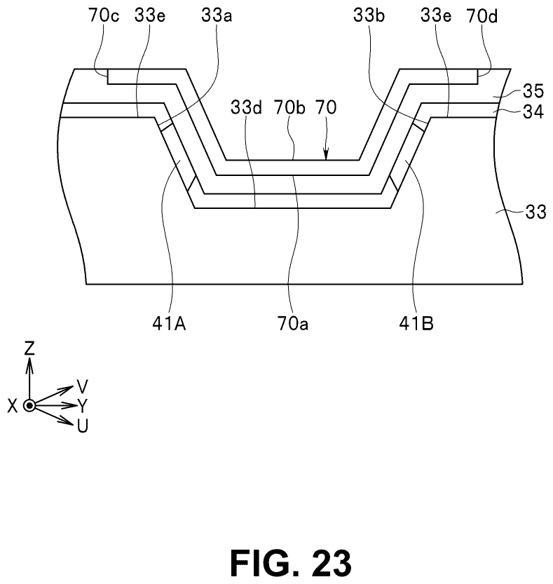

Next, the seventh modification example will be described with reference to FIG. 23. FIG. 23 is a sectional view showing a part of a magnetic sensor of the seventh modification example. In the seventh modification example, each of a plurality of first inclined surfaces 33a and a plurality of second inclined surfaces 33b is formed in a planar or nearly planar shape. Each of a plurality of protruding surfaces 33c further includes a top surface 33e located between the first inclined surface 33a and the second inclined surface 33b. The top surface 33e may be a surface substantially parallel to the top surface 31a of the substrate 31.

The shape of the protruding surface 33c in a cross section parallel to the YZ plane may be a trapezoidal shape. The overall shape of each of the plurality of protruding surfaces 33c is a solid surface formed by moving the trapezoidal shape along the direction parallel to the X direction.

In the seventh modification example, side surfaces 70c and 70d of the magnetic field generator 70 are located above a top surface 33e. The top surface 33e is a flat surface compared with the first and second inclined surfaces 33a and 33b. Therefore, in the seventh modification example, variation in the angle that each of the side surfaces 70c and 70d forms with respect to the top surface 33e, that is, the angle that each of the side surfaces 70c and 70d forms with respect to the top surface 31a of the substrate 31 can be suppressed. Thereby, it is possible to suppress the variations in the strength of the bias magnetic field to be applied to the first MR element 50A and the strength of the bias magnetic field to be applied to the second MR element 50B.

### Second Example Embodiment

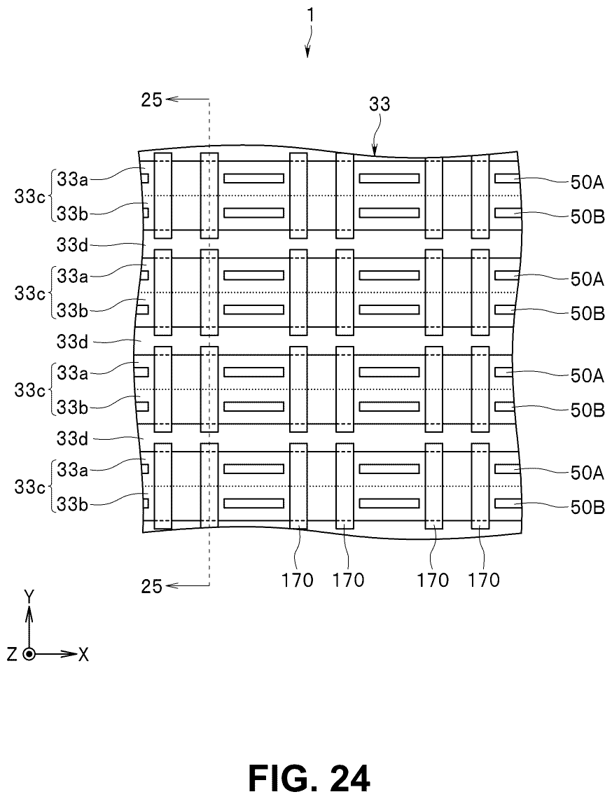

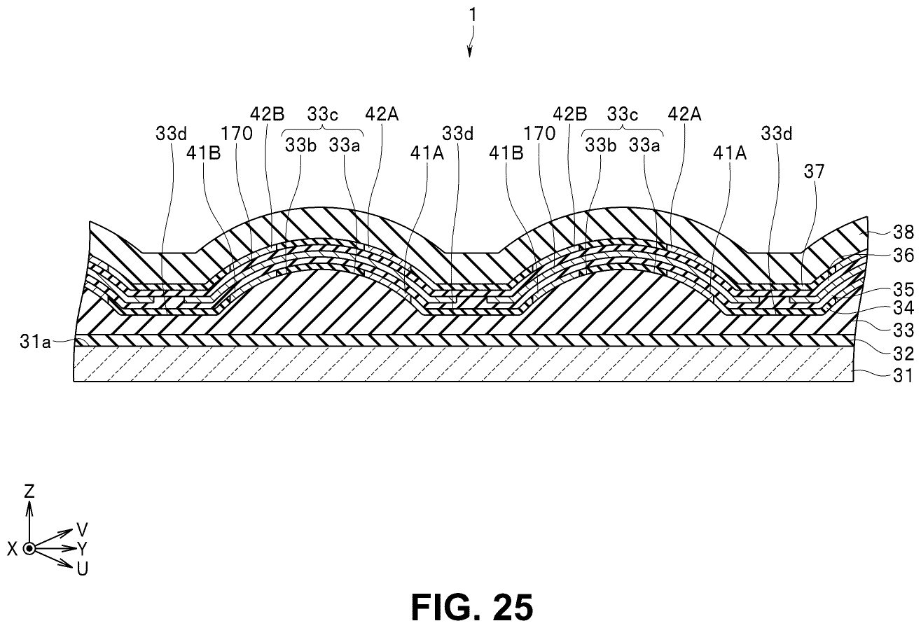

A second example embodiment of the disclosure will now be described with reference to FIGS. 24 and 25. FIG. 24 is a cross-sectional view showing a part of a magnetic sensor of the example embodiment. FIG. 25 shows a part of the cross section at the position indicated by the line 25-25 in FIG. 24.

The following describes how the configuration of a magnetic sensor 1 according to the example embodiment differs from that in the first example embodiment. The magnetic sensor 1 according to the example embodiment includes a plurality of magnetic field generators 170, instead of the plurality of magnetic field generators 70 in the first example embodiment. Each of the plurality of magnetic field generators 170 is disposed above one protruding surface 33c. In other words, each of the plurality of magnetic field generators 170 is disposed from a first inclined surface 33a to a second inclined surface 33b of one protruding surface 33c. Each of the plurality of magnetic field generators 170 includes a part located above the first inclined surface 33a of the one protruding surface 33c and a part located above the second inclined surface 33b of the one protruding surface 33c. Each of the plurality of magnetic field generators 170 further includes a part located above a flat surface 33d adjacent to the first inclined surface 33a and a part located above a flat surface 33d adjacent to the second inclined surface 33b.

Each of the plurality of magnetic field generators 170 may include a first end portion and a second end portion at both ends in the direction parallel to the Y direction. At least one of the first end portion or the second end portion may be located above the flat surface 33d. In the example embodiment, in particular, each of the first and second end portions is located above the flat surface 33d.

The configuration, operation, and effects of the example embodiment are otherwise the same as those of the first example embodiment.

### Third Example Embodiment

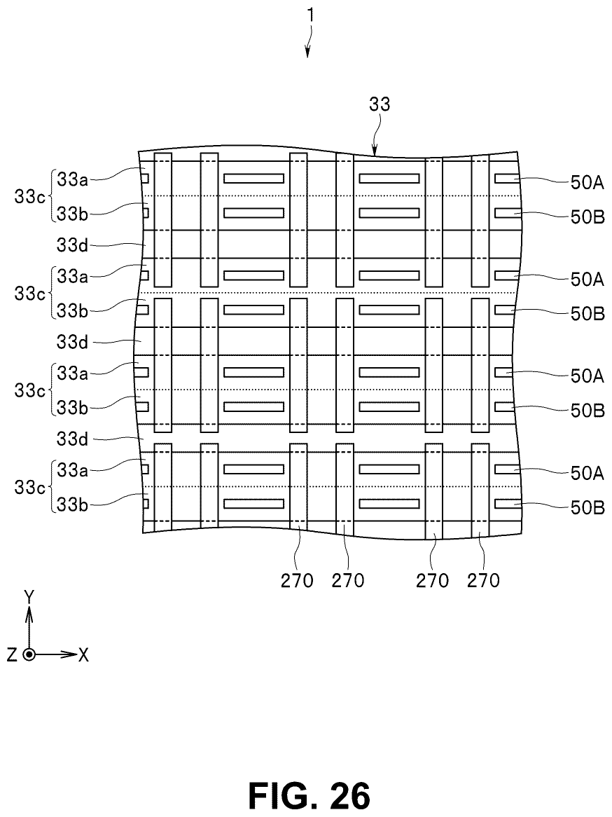

Next, a third example embodiment of the disclosure will be described with reference to FIG. 26. FIG. 26 is a cross-sectional view showing a part of a magnetic sensor of the example embodiment.

The following describes how the configuration of a magnetic sensor 1 according to the example embodiment differs from that in the first example embodiment. The magnetic sensor 1 according to the example embodiment includes a plurality of magnetic field generators 270, instead of the plurality of magnetic field generators 70 in the first example embodiment. Each of the plurality of magnetic field generators 270 is disposed so as to overlap three MR elements 50, when viewed in the X direction.

In the example shown in FIG. 26, the plurality of magnetic field generators 270 include a plurality of first magnetic field generators, each of which apply a bias magnetic field to two first MR elements 50A and one second MR element 50B, and a plurality of second magnetic field generators, each of which apply a bias magnetic field to one first MR element 50A and two second MR element 50B.

Each of the plurality of first magnetic field generators is disposed above two protruding surfaces 33c adjacent to each other in the direction parallel to the Y direction. Each of the plurality of first magnetic field generators is disposed from a first inclined surface 33a of one of the two protruding surfaces 33c to a first inclined surface 33a of the other of the two protruding surfaces 33c. Each of the plurality of first magnetic field generators includes: a part located above the first inclined surface 33a of the one of the two protruding surfaces 33c; a part located above the second inclined surface 33b of the other of the two protruding surfaces 33c; a part located above the first inclined surface 33a of the other of the two protruding surfaces 33c; and a part located above a flat surface 33d interposed between the two protruding surfaces 33c.

Each of the plurality of first magnetic field generators may include a first end portion and a second end portion located at both ends in the direction parallel to the Y direction. At least one of the first end portion or the second end portion is located above the flat surface 33d. In the example embodiment, in particular, one of the first and second end portions is located above the flat surface 33d, and the other of the first and second end portions is located above the first inclined surface 33a.

Each of the plurality of second magnetic field generators is located above two protruding surfaces 33c adjacent to each other in the direction parallel to the Y direction. Each of the plurality of second magnetic field generators is disposed from the second inclined surface 33b of one of the two protruding surfaces 33c to the second inclined surface 33b of the other of the two protruding surfaces 33c. Each of the plurality of second magnetic field generators includes: a part located above the second inclined surface 33b of the one of the two protruding surfaces 33c; a part located above the first inclined surface 33a of the one of the two protruding surfaces 33c; a part located above the second inclined surface 33b of the other of the two protruding surfaces 33c; and a part located above a flat surface 33d interposed between the two protruding surfaces 33c.

Each of the plurality of second magnetic field generators may include a first end portion and a second end portion located at both ends in the direction parallel to the Y direction. At least one of the first end portion or the second end portion is located above the flat surface 33d. In the example embodiment, in particular, one of the first and second end portions is located above the flat surface 33d, and the other of the first and second end portions is located above the second inclined surface 33b.

The configuration, operation, and effects of the example embodiment are otherwise the same as those of the first example embodiment.

### Fourth Example Embodiment

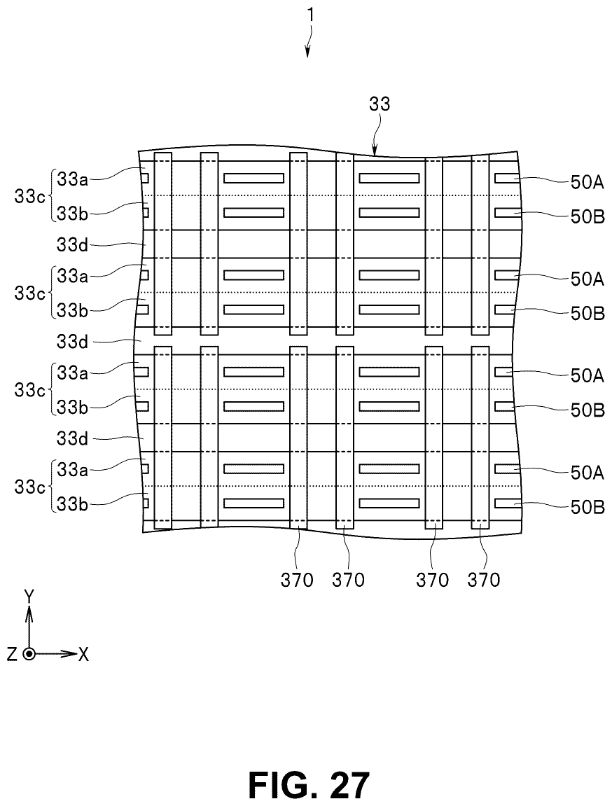

Next, a fourth example embodiment of the disclosure will be described with reference to FIG. 27. FIG. 27 is a cross-sectional view showing a part of a magnetic sensor of the example embodiment.

The following describes how the configuration of a magnetic sensor 1 according to the example embodiment differs from that in the first example embodiment. The magnetic sensor 1 according to the example embodiment includes a plurality of magnetic field generators 370, instead of the plurality of magnetic field generators 70 in the first example embodiment. Each of the plurality of magnetic field generators 370 is disposed so as to overlap four MR elements 50, when viewed in the X direction.

Each of the plurality of magnetic field generators 370 is disposed above two protruding surfaces 33c adjacent to each other in the direction parallel to the Y direction. Each of the plurality of magnetic field generators 370 is disposed from a second inclined surface 33b of one of two protruding surfaces 33c to a first inclined surface 33a of the other of the two protruding surfaces 33c. Each of the plurality of magnetic field generators 370 includes: a part located above the second inclined surface 33b of the one of the two protruding surfaces 33c; a part located above the first inclined surface 33a of the one of the two protruding surfaces 33c; a part located above the second inclined surface 33b of the other of the two protruding surfaces 33c; a part located above the first inclined surface 33a of the other of the two protruding surfaces 33c; and a part located above the flat surface 33d interposed between the two protruding surfaces 33c.

Each of the plurality of magnetic field generators 370 may include a first end portion and a second end portion located at both ends in the direction parallel to the Y direction. The first and second end portions are located above the flat surface 33d.

The configuration, operation, and effects of the example embodiment are otherwise the same as those of the first example embodiment.

Note that the disclosure is not limited to each of the foregoing example embodiments, and various modifications may be made thereto. For example, the magnetic sensor 1 of the disclosure may further include a third detection circuit configured to detect a component of the target magnetic field in the direction parallel to the X direction, and generate at least one third detection signal having a correspondence with this component. In such a case, the processor 2 may be configured to generate, based on the at least one third detection signal, a detection value corresponding to the component of the target magnetic field in the direction parallel to the X direction. The third detection circuit may be integrated with the first and second detection circuits 10 and 20, or may be included in a chip separate from the first and second detection circuits 10 and 20.

As described above, a magnetic sensor according to one embodiment of the disclosure includes: a substrate having a reference plane; a support member having a top surface including a first inclined surface and a second inclined surface that are inclined relative to the reference plane and oriented in directions different from each other; a first magnetoresistive element disposed above the first inclined surface; a second magnetoresistive element disposed above the second inclined surface; and a first magnetic field generator and a second magnetic field generator that are disposed from the first inclined surface to the second inclined surface, with the first magnetoresistive element and the second magnetoresistive element interposed between the first magnetic field generator and the second magnetic field generator, the first magnetic field generator and the second magnetic field generator each being configured to apply a bias magnetic field to the first magnetoresistive element and the second magnetoresistive element.

In the magnetic sensor according to one embodiment of the disclosure, each of the first magnetic field generator and the second magnetic field generator may include a first end portion and a second end portion located at both ends in a direction in which the first magnetoresistive element and the second magnetoresistive element are arranged. When a cross section that intersects the first magnetoresistive element and the second magnetoresistive element is defined as a first cross section, a cross section that is parallel to the first cross section and intersects the first magnetic field generator or the second magnetic field generator is defined as a second cross section, a position on the top surface of the support member, which is closest to the first end portion in the second cross section, is defined as a first position, a position on the top surface of the support member, which is closest to the second end portion in the second cross section, is defined as a second position, and a given position on the top surface of the support member, which overlaps the first magnetoresistive element and the second magnetoresistive element, when viewed in a direction perpendicular to the reference plane, in the first cross section is defined as a third position, a first angle that the top surface of the support member forms with respect to the reference plane at the first position and a second angle that the top surface of the support member forms with respect to the reference plane at the second position may be smaller than an angle that the top surface of the support member forms with respect to the reference plane at the third position.

In addition, the magnetic sensor according to one embodiment of the disclosure may further include a first electrode and a second electrode that are each formed of a conductive material, and an insulating layer. The first electrode may be in contact with the first magnetoresistive element, and the second electrode may be in contact with the second magnetoresistive element. The insulating layer may be interposed between the first and second magnetic field generators and the first and second electrodes, and may insulate the first and second magnetic field generators from the first and second electrodes.

In addition, in the magnetic sensor according to one embodiment of the disclosure, the insulating layer may cover a part of each of the first magnetoresistive element and the second magnetoresistive element.

In addition, in the magnetic sensor according to one embodiment of the disclosure, the first magnetoresistive element and the second magnetoresistive element do not have to be in contact with the first magnetic field generator and the second magnetic field generator.

In addition, in the magnetic sensor according to one embodiment of the disclosure, the top surface of the support member may further include a first protruding surface including the first inclined surface and a second protruding surface including the second inclined surface.

In addition, in the magnetic sensor according to one embodiment of the disclosure, the top surface of the support member may further include a flat surface which is located between the first inclined surface and the second inclined surface and which is substantially parallel to the reference plane.

In addition, in the magnetic sensor according to one embodiment of the disclosure, the top surface of the support member may further include a protruding surface including the first inclined surface and the second inclined surface.

In addition, in the magnetic sensor according to one embodiment of the disclosure, the top surface of the support member may further include a flat surface substantially parallel to the reference plane. The flat surface may be adjacent to at least one of the first inclined surface or the second inclined surface.

In addition, in the magnetic sensor according to one embodiment of the disclosure, each of the first magnetic field generator and the second magnetic field generator may include a first end portion and a second end portion located at both ends in a direction in which the first magnetoresistive element and the second magnetoresistive element are arranged. At least one of the first end portion or the second end portion may be located above the flat surface.

In the magnetic sensor of the disclosure, each of the first magnetic field generator and the second magnetic field generator is disposed from the first inclined surface to the second inclined surface. With such a configuration, according to the disclosure, variation in the strengths of the bias magnetic fields to be applied to the magnetoresistive elements can be suppressed.

Obviously, various aspects and modification examples of the disclosure can be implemented in the light of the above teachings. Thus, within the scope of the appended claims and equivalents thereof, the disclosure may be implemented in other embodiments other than the foregoing example embodiments.

1. A magnetic sensor comprising:
a substrate having a reference plane;
a support member having a top surface including a first inclined surface and a second inclined surface that are inclined relative to the reference plane and oriented in directions different from each other;
a first magnetoresistive element disposed above the first inclined surface;
a second magnetoresistive element disposed above the second inclined surface; and
a first magnetic field generator and a second magnetic field generator that are disposed from the first inclined surface to the second inclined surface, with the first magnetoresistive element and the second magnetoresistive element interposed between the first magnetic field generator and the second magnetic field generator, the first magnetic field generator and the second magnetic field generator each being configured to apply a bias magnetic field to the first magnetoresistive element and the second magnetoresistive element.

2. The magnetic sensor according to claim 1, wherein
each of the first magnetic field generator and the second magnetic field generator includes a first end portion and a second end portion located at both ends in a direction in which the first magnetoresistive element and the second magnetoresistive element are arranged, and
when a cross section that intersects the first magnetoresistive element and the second magnetoresistive element is defined as a first cross section, a cross section that is parallel to the first cross section and intersects the first magnetic field generator or the second magnetic field generator is defined as a second cross section, a position on the top surface of the support member, which is closest to the first end portion in the second cross section, is defined as a first position, a position on the top surface of the support member, which is closest to the second end portion in the second cross section, is defined as a second position, and a given position on the top surface of the support member, which overlaps the first magnetoresistive element and the second magnetoresistive element, when viewed in a direction perpendicular to the reference plane, in the first cross section is defined as a third position, a first angle that the top surface of the support member forms with respect to the reference plane at the first position and a second angle that the top surface of the support member forms with respect to the reference plane at the second position are smaller than an angle that the top surface of the support member forms with respect to the reference plane at the third position.

3. The magnetic sensor according to claim 1, further comprising:
a first electrode and a second electrode that are each formed of a conductive material; and
an insulating layer, wherein
the first electrode is in contact with the first magnetoresistive element,
the second electrode is in contact with the second magnetoresistive element, and
the insulating layer is interposed between the first and second magnetic field generators and the first and second electrodes, and configured to insulate the first and second magnetic field generators from the first and second electrodes.

4. The magnetic sensor according to claim 3, wherein the insulating layer covers a part of each of the first magnetoresistive element and the second magnetoresistive element.

5. The magnetic sensor according to claim 1, wherein the first magnetoresistive element and the second magnetoresistive element are not in contact with the first magnetic field generator and the second magnetic field generator.

6. The magnetic sensor according to claim 1, wherein the top surface of the support member further includes a first protruding surface including the first inclined surface and a second protruding surface including the second inclined surface.

7. The magnetic sensor according to claim 6, wherein the top surface of the support member further includes a flat surface located between the first inclined surface and the second inclined surface, the flat surface being substantially parallel to the reference plane.

8. The magnetic sensor according to claim 1, wherein the top surface of the support member further includes a protruding surface including the first inclined surface and the second inclined surface.

9. The magnetic sensor according to claim 8, wherein the top surface of the support member further includes a flat surface substantially parallel to the reference plane, and the flat surface is adjacent to at least one of the first inclined surface or the second inclined surface.

10. The magnetic sensor according to claim 9, wherein
each of the first magnetic field generator and the second magnetic field generator includes a first end portion and a second end portion located at both ends in a direction in which the first magnetoresistive element and the second magnetoresistive element are arranged, and
at least one of the first end portion or the second end portion is located above the flat surface.
